(19) United States
(12) Patent Application Publication
(10) Pub. No.: US 2024/0333251 A1
(43) Pub. Date: Oct. 3, 2024

(54) BULK ACOUSTIC WAVE STRUCTURES WITH CONDUCTIVE BRIDGE STRUCTURES

(71) Applicant: Qorvo US, Inc., Greensboro, NC (US)

(72) Inventor: Yazid Yusuf, Orlando, FL (US)

(21) Appl. No.: 18/611,515

(22) Filed: Mar. 20, 2024

Related U.S. Application Data
(60) Provisional application No. 63/492,393, filed on Mar. 27, 2023.

(51) Int. Cl. H03H 9/13

(52) U.S. Cl. CPC H03H 9/132

(57) ABSTRACT

A bulk acoustic wave (BAW) is provided. The BAW structure includes a transducer that includes a first electrode, a second electrode, a piezoelectric layer between the first electrode and the second electrode, and a conductive bridge structure extending in a lateral direction and in contact with the first electrode at a central stripe area of the first electrode.

### CROSS-REFERENCE TO RELATED APPLICATION

This application claims priority to U.S. Provisional Application No. 63/492,393 filed on Mar. 27, 2023, the benefit of which is claimed and the disclosure of which is incorporated herein in its entirety.

### FIELD OF THE INVENTION

This disclosure relates to bulk acoustic wave (BAW) structures. In particular, this disclosure relates to BAW structures with conductive bridge structures connected to the electrodes of BAW structures.

### BACKGROUND

Acoustic resonators, e.g., particularly Bulk Acoustic Wave (BAW) resonators or BAW filters, are used in high-frequency communication applications such as 3^{rd} Generation (3G), 4^{th} Generation (4G), and 5^{th} Generation (5G) wireless devices. In particular, a BAW resonator is often employed to provide a flat passband, steep filter skirts, and squared shoulders at the upper and lower ends of the passband, and provide excellent rejection outside of the passband in a filter network. BAW resonators also have relatively low insertion loss, tend to decrease in size as the frequency of operation increases, and are relatively stable over wide temperature ranges. These wireless devices often support various communication means such as cellular, wireless fidelity (Wi-Fi), Bluetooth, and/or near field communications, and accordingly, high performance of the BAW resonators are needed.

To meet filtering requirements in certain applications, a BAW resonator that operates at higher frequencies often has thinner electrodes and/or a smaller resonating area. As a result, the BAW resonator can have higher electrical loss, which can negatively affect its performance. Thus, there is a need to improve the performance of the BAW resonators.

### SUMMARY

Aspects of the invention provides a BAW structure. The BAW structure includes a transducer that includes a first electrode, a second electrode, a piezoelectric layer between the first electrode and the second electrode, and a conductive bridge structure extending in a lateral direction and in contact with the first electrode at a central stripe area of the first electrode.

In some embodiments, the transducer further includes a second conductive bridge structure extending in the lateral direction and in contact with the second electrode at a central stripe area of the second electrode, the central stripe area of the first electrode and the central stripe area of the second electrode are aligned with each other in the lateral direction.

In some embodiments, the conductive bridge structure is in contact with a first peripheral area of the first electrode, and the second conductive bridge structure is in contact with a second peripheral area of the second electrode. The first peripheral area and the second peripheral area are on opposite sides of the central stripe areas of the first electrode and the second electrode.

In some embodiments, the transducer further includes a second conductive bridge structure over and in contact with the second electrode at two peripheral areas of the second electrode. The two peripheral areas are on opposite sides of the central stripe area of the first electrode.

In some embodiments, the transducer further includes a third conductive bridge structure extending in a second lateral direction, intersecting with the conductive bridge structure, and in contact with the first electrode at a second central stripe area of the first electrode. In some embodiments, the transducer further includes a fourth conductive bridge structure extending in the second lateral direction, intersecting with the second conductive bridge structure, and in contact with the second electrode at a second central stripe area of the second electrode. The second central stripe area of the first electrode and the second central stripe area of the second electrode are aligned with each other, the second lateral direction being different from the lateral direction.

In some embodiments, the transducer further includes a third conductive bridge structure extending in a second lateral direction, intersecting with the conductive bridge structure, and in contact with the first electrode at a second central stripe area of the first electrode. In some embodiments, a fourth conductive bridge structure extending in the second lateral direction, intersecting with the second conductive bridge structure, and in contact with the second electrode at a second central stripe area of the second electrode. The second central stripe area of the first electrode and the second central stripe area of the second electrode are aligned with each other, the second lateral direction being different from the lateral direction.

In some embodiments, the transducer further includes a third conductive bridge structure extending in a second lateral direction, intersecting with the conductive bridge structure, and in contact with the first electrode at a second central stripe area of the first electrode, the second lateral direction being different from the lateral direction. The second conductive bridge structure is in contact with the second electrode at all peripheral areas of the second electrode.

In some embodiments, the conductive bridge structure is in contact with the second electrode at a central stripe area of the second electrode, the central stripe areas of the first electrode and the second electrode having no overlap and being aligned with each other in the lateral direction. In some embodiments, the central stripe areas of the first electrode and the second electrode divide the transducer into a first sub-transducer and a second sub-transducer, and the first sub-transducer includes a first portion of the first electrode and a first portion of the second electrode. The second sub-transducer includes second portion of the first electrode and a second portion of the second electrode.

In some embodiments, the conductive bridge structure includes a first bridge portion in contact with the central stripe area of the first electrode and surrounds a peripheral area of the first portion of the first electrode, and a second bridge portion in contact with the central stripe area of the second electrode and surrounds a peripheral area of the second portion of the second electrode. The first bridge portion and the second bridge portion may be located in parallel planes.

In some embodiments, the first bridge portion and the second bridge portion are conductively connected by a conductive via through the piezoelectric layer.

In some embodiments, the first and second portions of the first electrode are in contact with each other through the central stripe area of the first electrode, and the first and second portions of the second electrode are in contact with each other through the central stripe area of the second electrode.

In some embodiments, the first portion of the first electrode is disconnected from the second portion of the first electrode by the central stripe area of the first electrode, the first portion of the second electrode is disconnected from the second portion of the second electrode by the central stripe area of the second electrode, and the first portion of the first electrode is conductive connected to the second portion of the second electrode. The first portion of the second electrode may be conductively connected to the second portion of the first electrode.

In some embodiments, the transducer further includes a second conductive bridge structure in contact with the second electrode at all peripheral areas of the second electrode, and a vertical projection of the first electrode is surrounded by a vertical projection of the second conductive bridge structure.

In some embodiments, the second conductive bridge structure is disposed in a single plane.

In some embodiments, a vertical projection of the conductive bridge structure is line of symmetry of the vertical projection of the second conductive bridge structure.

In some embodiments, the second electrode includes a first portion and a second portion, and vertical projections of the first portion and the second portion of the second electrode are disposed on opposite sides of the vertical projection of the conductive bridge structure.

In some embodiments, the vertical projections of the first portion and the second portion of the second electrode do not overlap with the vertical projection of the conductive bridge structure.

In some embodiments, the conductive bridge structure includes alternating one or more first metal layers and one or more second metal layers, the first metal layers and the second metal layers having different acoustic impedances.

In some embodiments, the second conductive bridge structure includes alternating one or more first metal layers and one or more second metal layers, the first metal layers and the second metal layers having different acoustic impedances.

In some embodiments, an area outside central stripe area of the first electrode is covered with a dielectric material.

In some embodiments, the BAW structure further includes a second conductive bridge structure extending in contact with the second electrode at a second central stripe area of the second electrode, the central stripe area of the first electrode and the second central stripe area of the second electrode are aligned with each other in the lateral direction and separated by a gap. The central stripe areas of the first electrode and the second electrode divide the transducer into a first sub-transducer and a second sub-transducer, the first sub-transducer and the second sub-transducer being separated by a second gap. The first electrode is divided to a first electrode of the first sub-transducer and a first electrode of the second sub-transducer, and the second electrode is divided to a second electrode of the first sub-transducer and a second electrode of the second sub-transducer. The first conductive bridge structure is electrically disconnected from the second conductive bridge structure.

In some embodiments, the conductive bridge structure is in contact with a peripheral area of the first electrode in the first sub-transducer, the second conductive bridge structure is in contact with a peripheral area of the second electrode in the second sub-transducer, and a projection of the conductive bridge structure has no overlap with a projection of the second conductive bridge structure.

In some embodiments, the second conductive bridge structure is in a same plane of the conductive bridge structure, and is electrically connected to the second electrode of the second sub-transducer with a conductive via through the piezoelectric layer.

In some embodiments, the conductive bridge structure is in contact with a peripheral area of the first electrode in the first sub-transducer, the second conductive bridge structure is in contact with a peripheral area of the first electrode in the second sub-transducer and is in a same plane of the conductive bridge structure, and the first electrode of the first sub-transducer is electrically disconnected from the first electrode of the second sub-transducer and electrically connected to the second electrode of the second sub-transducer with a conductive via through the piezoelectric layer. A projection of the conductive via is overlapped with the central stripe area. The second electrode of the first sub-transducer is electrically disconnected from the second electrode of the second sub-transducer and is electrically connected to the first electrode of the second sub-transducer with another conductive via through the piezoelectric layer. A projection of the other conductive via is overlapped with the second central stripe area; and

In some embodiments, the transducer further includes a second conductive structure in contact with the second electrode at all peripheral areas of the second electrode, and a vertical projection of the first electrode is surrounded by a vertical projection of the second conductive structure.

In some embodiments, the second conductive structure is disposed in a single plane.

In some embodiments, a vertical projection of the central stripe area is a line of symmetry of the vertical projection of the second conductive bridge structure.

In some embodiments, the second electrode comprises a first portion and a second portion; and vertical projections of the first portion and the second portion of the second electrode are disposed on opposite sides of the vertical projection of the central stripe area and have no overlap with each other.

In some embodiments, the conductive bridge structure include a stack of alternating one or more first metal layers and one or more second metal layers in contact with the first electrode, the first metal layers and the second metal layers having different acoustic impedances.

In some embodiments, the second conductive bridge structure includes alternating one or more first metal layers and one or more second metal layers, the first metal layers and the second metal layers having different acoustic impedances.

In some embodiments, an area outside central stripe area of the first electrode is covered with a dielectric material.

Embodiments of the present disclosure provide a BAW structure having a transducer. The transducer includes a first electrode, a second electrode, a piezoelectric layer between the first electrode and the second electrode, a first conductive structure in contact with a peripheral area of the first electrode, and a second conductive structure in contact with a peripheral area of the second electrode. The first conductive structure or the second conductive structure includes a stack of alternating one or more first metal layers and one or more second metal layers. The first metal layers and the second metal layers have different acoustic impedances.

In some embodiments, the first conductive structure includes a central portion in contact with the first electrode along a line of symmetry of the transducer and a peripheral portion of the first conductive structure, and the second conductive structure includes a central portion in contact with the second electrode along the line of symmetry of the transducer and a peripheral portion of the second conductive structure. The central portion of the first conductive structure or the central portion of the second conductive structure comprises another stack of alternating one or more first metal layers and one or more second metal layers.

### BRIEF DESCRIPTION OF THE DRAWINGS

FIGS. 1A and 1B each illustrates a side view of an existing BAW resonator with current distribution, and ohmic losses in the respective BAW resonator.

FIG. 2A illustrates a side view of an exemplary BAW structure with current distribution, according to some embodiments of the present disclosure.

FIG. 2B illustrates a side view of an existing BAW structure with current distribution, and ohmic losses.

FIG. 2C illustrates a side view of an exemplary BAW structure with current distribution, and ohmic losses, according to some embodiments of the present disclosure.

FIG. 2D illustrates a side view of an exemplary BAW structure depicting alternating layers of low/high impedance conductive layers, according to some embodiments of the present disclosure.

FIGS. 3A, 3B, and 3C respectively illustrate a side view, a top view, and a bottom view of an exemplary BAW structure, according to some embodiments of the present disclosure.

FIGS. 4A, 4B, and 4C respectively illustrate a side view, a top view, and a bottom view of another exemplary BAW structure, according to some embodiments of the present disclosure.

FIGS. 5A, 5B, and 5C respectively illustrate a side view, a top view, and a bottom view of another exemplary BAW structure, according to some embodiments of the present disclosure.

FIGS. 6A, 6B, and 6C respectively illustrate a side view, a top view, and a bottom view of another exemplary BAW structure, according to some embodiments of the present disclosure

FIGS. 7A, 7B, and 7C respectively illustrate a side view, a top view, and a bottom view of another exemplary BAW structure, according to some embodiments of the present disclosure.

FIGS. 8A, 8B, and 8C respectively illustrate a side view, a top view, and a bottom view of another exemplary BAW structure, according to some embodiments of the present disclosure.

FIGS. 9A and 9B each illustrates a top view of another exemplary BAW structure, according to some embodiments of the present disclosure.

FIGS. 10A and 10B respectively illustrates a side view and a top view of another exemplary BAW structure, according to some embodiments of the present disclosure.

FIGS. 11A and 11B respectively illustrates a side view and a top view of another exemplary BAW structure, according to some embodiments of the present disclosure.

FIGS. 12A and 12B respectively illustrates a side view and a top view of another exemplary BAW structure, according to some embodiments of the present disclosure.

FIGS. 13A and 13B respectively illustrates a side view and a top view of another exemplary BAW structure, according to some embodiments of the present disclosure.

### DETAILED DESCRIPTION

The following detailed description is illustrative in nature and is not intended to limit the scope, applicability, or configuration of inventive embodiments disclosed herein in any way. Rather, the following description provides practical examples, and those skilled in the art will recognize that some of the examples may have suitable alternatives. Embodiments will hereinafter be described in conjunction with the appended drawings, which are not to scale (unless so stated), wherein like numerals/letters denote like elements. However, it will be understood that the use of a number to refer to a component in a given drawing is not intended to limit the component in another drawing labeled with the same number. In addition, the use of different numbers to refer to components in different drawings is not intended to indicate that the different numbered components cannot be the same or similar to other numbered components. Examples of constructions, materials, dimensions and fabrication processes are provided for select elements and all other elements employ that which is known by those skilled in the art.

As used herein, the term “about” refers to a given amount of value that may vary based on the particular technology node associated with the semiconductor device. Based on a particular technology node, the term “about” can refer to a given amount of value that varies, for example, within 10-30% of the value (e.g., ±10%, ±20%, or ±20% of that value, or ±30%).

As used herein, the term “bridge structure” refers to a conductive structure of sufficiently high conductivity and in contact with an electrode. In some embodiments, a bridge structure electrically bridge/conduct different parts of the electrode. In some embodiments, a bridge structure may not electrically bridge/conduct different parts of the electrode.

Reference will now be made in greater detail to various embodiments of the subject matter of the present disclosure, some embodiments of which are illustrated in the accompanying drawings.

To meet the filtering needs of 5G networks, BAW resonators operating at higher frequencies (>5 GHZ) are in demand. Higher frequencies of operation bring about several challenges to BAW technology. Layer thicknesses generally scale as 1/f (f being the operating frequency). The scaling results in thinner electrodes and consequently increased sheet resistances and electrical losses. Additionally, resonating areas become smaller (e.g., they scale as 1/f²). The smaller resonating areas pose problems to BAW resonators' ability to handle high power levels. Typically, this is addressed by cascading multiple resonators in series. By taking advantage of voltage division and increased resonator areas, the power dissipation density is effectively decreased. The main drawback of this approach is the added resistance due to the series connections, which compounds the problem of already large sheet resistances at higher frequencies.

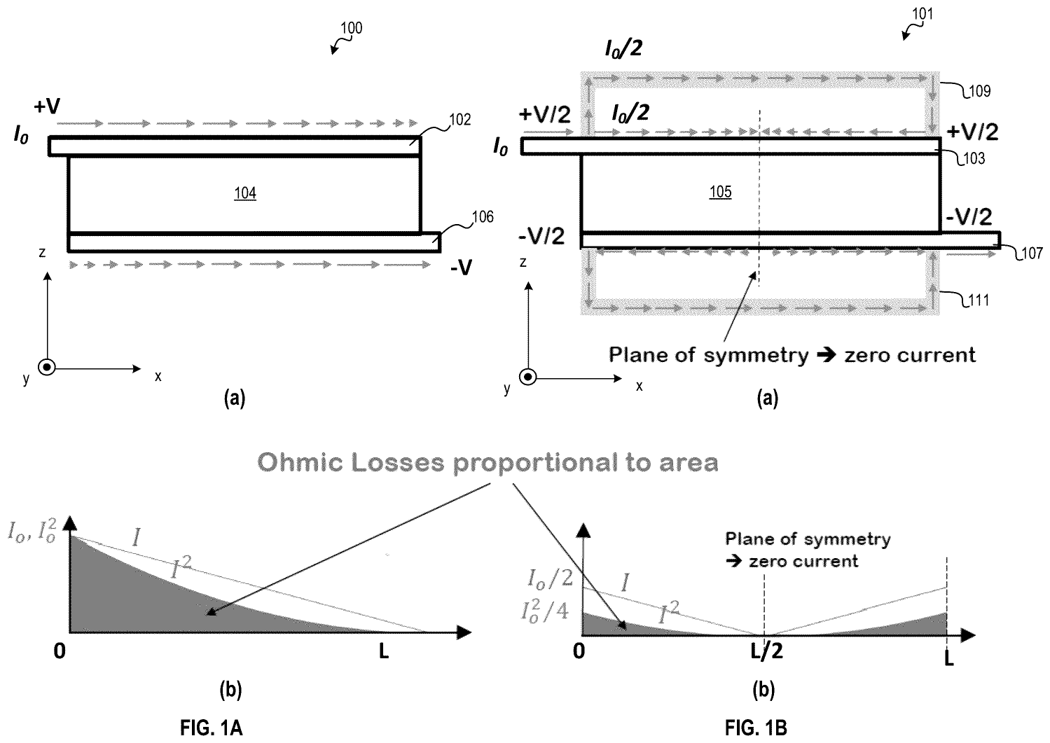

FIG. 1A illustrates a side view of (a) a simplified existing BAW resonator 100 with current distribution, and (b) electrical losses as a function of distance. It is assumed the resonating area, e.g., the overlapping area(s) between a piezoelectric layer and the two electrodes, has a length of L. As shown in (a), BAW resonator 100 includes a first electrode (e.g., top electrode) 102, a second electrode (e.g., bottom electrode) 106, and a piezoelectrical layer 104 disposed between first electrode 102 and second electrode 106. First electrode 102 and second electrode 106 can include a conductive material such as tungsten and/or aluminum copper. Piezoelectric layer 104 can include a piezoelectric material such as aluminum nitride. As shown in FIG. 1A, BAW resonator 100 does not include a conductive bridge. In operation, electrical current flows from one end of the electrodes to the other end of the electrodes, and BAW resonator 100 converts between electric and acoustic energy. It is assumed the initial electrical current has an amplitude of lo at one end (e.g., location 0) of first and second electrodes 102 and 106. The direction of the current flow is indicated by the arrows. As shown in (b), the electrical current decreases from the initial amplitude (e.g., I₀) to zero at the other end (e.g., at location L). The electrical losses (e.g., I₀²) of BAW resonator 100 is proportional to the square of the initial electrical current (e.g., I₀) and decreases to zero when it reaches the other end (e.g., location L) of first and second electrodes 102 and 106.

FIG. 1B illustrates a side view of (a) a simplified existing BAW resonator 101 with current distribution, and (b) electrical losses as a function of distance. BAW resonator 101 includes one or more conductive bridges, and was disclosed in U.S. Pat. No. 11,528,007. As shown in (a), BAW resonator 101 includes a first electrode (e.g., top electrode) 103, a second electrode (e.g., bottom electrode) 107, and a piezoelectrical layer 105 disposed between first electrode 103 and second electrode 107. First electrode 103, second electrode 107, and piezoelectric layer 105 can be similar to their counterparts in BAW resonator 100. As shown in FIG. 1B, BAW resonator 101 includes a first (e.g., top) conductive bridge 109 electrically connecting the two ends of first electrode 103, and a second (e.g., bottom) conductive bridge 111 electrically connecting the two ends of second electrode 107 (e.g., two distal ends of second electrode 107). For case of illustration, the two ends of an electrode are also referred to as two outer ends for being away from the center (or the plane of symmetry) of the electrode. First conductive bridge 109 and second conductive bridge 111 include highly conductive materials such as tungsten and/or aluminum copper such that the ohmic resistance of the first and second conductive bridges 109 and 111 is negligible.

It is assumed the initial electrical current has an amplitude of I₀ before traveling in first and second electrodes 103 and 107. Because of the low ohmic resistance of first and second conductive bridges 109 and 111, potential drop along first and second conductive bridges 109 and 111, and first and second electrodes 103 and 107 can be considered zero (or negligible). As a result, the electric potential at the two outer ends of the first electrode 103 are identical and consequently the currents flowing into the outer ends are identical. Similarly, the electric potential at the two outer ends of the second electrode 107 are identical and consequently the currents flowing out of the outer ends are identical. Electrical current therefore flows from first electrode 103 (e.g., a higher potential) to second electrode 107 (e.g., a lower potential) splits in half (e.g., I₀/2) at the intersection between an electrode (e.g., 103 or 107) and the respective conductive bridge (e.g., 109 or 111), as shown in FIG. 1B. Electrical currents of the same amplitude (e.g., I₀/2) may flow in opposite directions in each first electrode 103 and second electrode 107, and can cause the total electrical current at the central position (e.g., the plane of symmetry) of first and second electrodes 103 and 107 to be about zero. As shown in (b), the electrical current decreases from half of the initial amplitude (e.g., I₀/2) to zero at the plane of symmetry (e.g., the central position of first and second electrodes 103 and 107, or L/2), and the electrical losses (e.g., I₀²/4) of BAW resonator 100 is proportional to the square of the split electrical current (I₀/2), and may decrease to zero to the plane of symmetry. Compared to BAW resonator 100, BAW resonator 101 can reduce the electrical current flows in the electrodes, and thus effectively reduce electrical losses thanks to the conductive bridges (e.g., 109 and 111).

To reduce the electrical loss in BAW resonators, embodiments of the present disclosure provide BAW structures, e.g., BAW resonators/filters, with reduced electrical loss compared to an existing BAW resonator. A disclosed BAW structure includes a first electrode, a second electrode, a piczoelectric layer between the first electrode and the second electrode, and a conductive bridge structure extending in a lateral direction and in contact with the first electrode at a first contact area of the first electrode. The contact area can be a central stripe area of the first electrode. The first electrode can be a top electrode or a bottom electrode. The disclosed BAW structure may also include a second conductive bridge structure in contact with the second electrode at a second contact area. The second contact area can be a central stripe area of the second electrode, or a peripheral area of the second electrode. The conductive bridge structure and the second conductive bridge structure each includes a conductive material of desirably high electrical conductivity such that the electrical resistivity of the conductive bridge structure and the second conductive bridge structure can be negligible. Instead of the first and second electrodes, the conductive bridge structure and the second conductive bridge structure can be biased to allow electrical current to flow from the first/second electrode from the respective conductive bridge structure. This configuration can reduce the electrical current in the electrodes, and thus reduce the electrical losses of the BAW structure.

A resonating area is formed between the overlapping area between the first electrode and the second electrode. When either the first contact area or the second contact area overlap with the resonating area of the BAW structure, the conductive bridge structure and/or the second conductive bridge structure may each include a stack structure of alternatingly arranged high/low impedance materials. The stack structure can reduce the acoustic loading on the contact areas on the electrode that's in contact with the respective conductive bridge structure. In some embodiments, when the first contact area and the second contact area has no overlap with the resonating area of the BAW structure, no stack structure is formed in the conductive bridge structure or second conductive bridge structure.

In some embodiments, the first electrode includes a first electrode portion and a second electrode portion, separated by a spacing, and the conductive bridge structure is disposed at the outer periphery of the first electrode. The second electrode overlaps with each of the first electrode portion and the second electrode portion, while the second contact area overlaps with the spacing in the vertical direction. In some embodiments, no stack structure is formed in the conductive bridge structure or the second conductive bridge structure.

In some embodiments, the first and second electrodes each includes a first electrode portion and a second electrode portion, separated by a central electrode portion. The conductive bridge structure may include two bridge portions respectively extending in the central electrode portions and respectively surround the electrode portions on opposite sides. The two bridge portions may be disposed in parallel planes. In some embodiments, the two bridge portions may be disposed in the same plane.

In some embodiments, the BAW structure includes at least a third conductive bridge structure in contact with the first electrode or the second electrode at a third contact area. The third contact area may overlap with the resonating area within the transducer When the third contact area overlaps with the resonating area of the transducer, a stack structure may be formed in the third conductive bridge structure.

Referring back to the description of FIG. 1B and BAW resonator 101, because the total electrical current at the plane of symmetry is equal to zero, BAW resonator 101 (or the resonating area) can be viewed as open circuit at the plane of symmetry. BAW resonator 101 (or the resonating area of BAW resonator 101) can then alternated by moving the plane of symmetry outwards while maintaining the same current flow directions in the first and second electrodes 103 and 107. The first and second conductive bridges 109 and 111 may then be connected to first electrode 103 and second electrode 107 at a central position (e.g., instead of at the two ends away from the central position in BAW resonator 101). In other words, the non-zero electrical current may flow from conductive bridge (e.g., 109 or 111) to the central position of the respective electrode (e.g., 103 or 107), and further to the outer ends of the respective electrode, decreasing to zero.

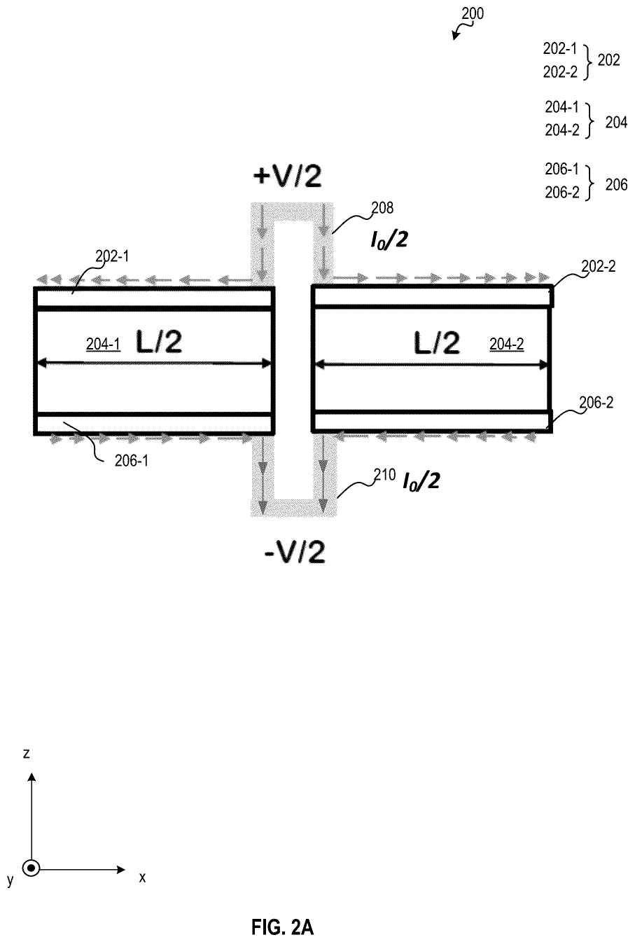

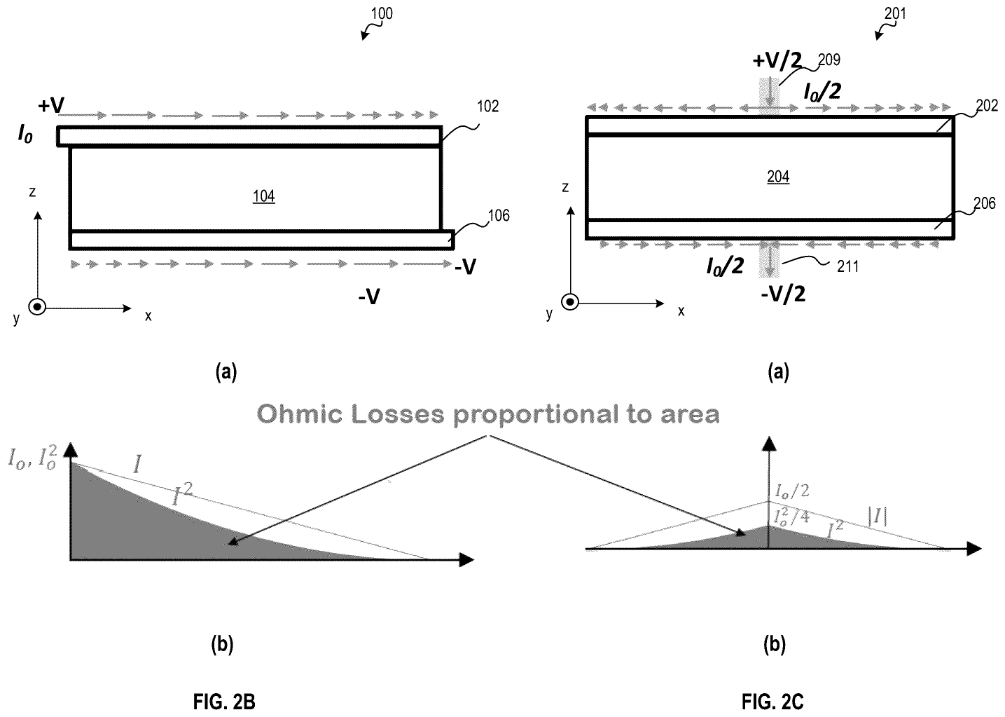

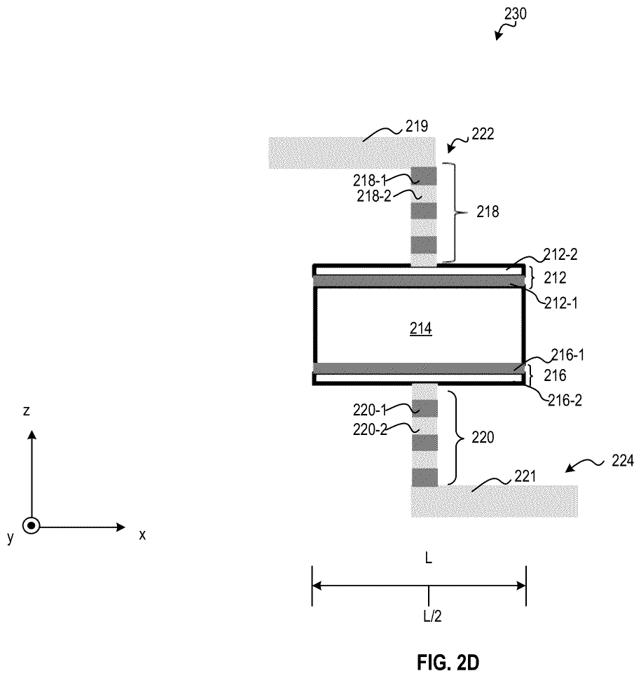

FIG. 2A illustrates an equivalent structural diagram 200 of BAW resonator 101. Structural diagram 200 is an alternate physical realization of BAW structure 101, and can have reduced electrical losses, as described above. Structural diagram 200 includes a pair of first electrodes 202-1 and 202-2, a pair of second electrodes 206-1 and 206-2, a pair of piezoelectric layers 204-1 and 204-2, a first conductive bridge 208, and a second conductive bridge 210. First conductive bridge 208 may be equivalent to first conductive bridge 109, and second conductive bridge 210 may be equivalent to second conductive bridge 111. The resonating area of structural diagram 200 (e.g., including first electrodes 202-1 and 202-2, second electrodes 206-1 and 206-2, and piezoelectric layers 204-1 and 204-2) can be equivalent to dividing the resonating area of BAW resonator 101 (e.g., including first electrode 105, second electrode 107, and piezoelectric layer 105) into two half resonating areas (e.g., each having a length of L/2) at the plane of symmetry, and rotating each of the two half resonating areas outwards (e.g., away from the plane of symmetry) such that the outer ends of an electrodes (e.g., 103 or 107) become inner ends of a respective pair of electrodes (202-1 and 202-2, or 206-1 and 206-2). Accordingly, the connections between first conductive bridge 109 and first electrode 103 (e.g., with non-zero electrical current at the two outer ends of first electrode 103) may be equivalent to the connections between first conductive bridge 208 and the pair of first electrodes 202-1 and 202-2 at the inner ends of first electrodes 202-1 and 202-2, and the connections between second conductive bridge 111 and second electrode 107 (e.g., with non-zero electrical current at the two outer ends of second electrode 107) may be equivalent to the connections between second conductive bridge 210 and the pair of second electrodes 206-1 and 206-2 at the inner ends of second electrodes 206-1 and 206-2. As described above, the ohmic resistances of first conductive bridge 208 and second conductive bridge 210 are negligible, any change in lengths of first conductive bridge 208 and second conductive bridge 210 do not result a change of structural diagram 200.

As shown in FIG. 2A, electrical current (e.g., I₀/2) may flow from first conductive bridge 208 into first electrodes 202-1 and 202-2, and may flow from second electrodes 206-1 and 206-2 further into second conductive bridge 210. Structural diagram 200 can be further simplified to another structural diagram 201, as shown in (a) of FIG. 2C. Structural diagram 201 includes a first electrode 202, a second electrode 206, and a piezoelectric layer 204. As described above, first electrode 202 is equivalent to the merging of first electrodes 202-1 and 202-2 at the inner ends, second electrode 206 is equivalent to the merging of first electrodes 206-1 and 206-2 at the inner ends, and piezoelectric layer 204 is equivalent to the merging of piezoelectric layers 204-1 and 204-2. A first conductive bridge structure 209 is equivalent to the merging of the two branches of first conductive bridge 208 connecting the inner ends of first electrodes 202-1 and 202-2, respectively. Similarly, a second conductive bridge structure 211 is equivalent to the merging of the two branches of second conductive bridge 210 connecting the inner ends of second electrodes 206-1 and 206-2, respectively. Compared to BAW resonator 100 (reproduced in FIG. 2B), structural diagram 201 can reduce the electrical losses by a factor of four.

FIG. 2D illustrates a BAW structure 230, a transducer, with reduced electrical losses, according to some embodiments. In some embodiments, BAW structure 230 is an implementation of structural diagram 201.

BAW structure 230 may include a first electrode 212, a second electrode 216, and a piezoelectric layer 214 between first electrode 212 and second electrode 216. First electrode 212 may include one or more suitable conductive materials, and may be a single-layer structure or a multi-layer structure. For example, first electrode 212 may include one or more of copper (Cu), tungsten (W), aluminum copper (AlCu), molybdenum (Mo), and/or platinum (Pt). In some embodiments, first electrode 212 includes a first layer 212-1 in contact of piezoelectric layer 214 on one side of piezoelectric layer 214, and a second layer 212-2 over and in contact with first layer 212-1. In some embodiments, second electrode 216 is similar to first electrode 212, and includes a first layer 216-1 in contact of piezoelectric layer 214 on the other side of piezoelectric layer 214, and a second layer 216-2 over and in contact of first layer 216-1. In some embodiments, first layers 212-1 and 216-1 each includes tungsten, and second layers 212-2 and 216-2 each includes aluminum copper. Piezoelectric layer 214 may include a suitable piezoelectric material such as aluminum nitride (AlN), zinc oxide (ZnO), aluminum scandium nitride (AlScN) and/or other suitable materials. In some embodiments, piezoelectric layer 214 includes AlN.

BAW structure 230 may include a first conductive bridge structure 222 electrically connected to (e.g., in contact with) first electrode 212, and a second conductive bridge structure 224 electrically connected to (e.g., in contact with) second electrode 216. Instead of first and second electrodes 212 and 216, first conductive bridge structure 222 and second conductive bridge 224 may be biased to conduct electrical current. First conductive bridge structure 222 and second conductive bridge structure 224 may each include highly conductive materials such as metals. Referring back to structural diagrams 200 and 201, first conductive bridge structure 222 and second conductive bridge structure 224 may each be in contact with (e.g., fed to) the respective electrode at the central position of the respective electrode. For example, the contact area between each of the first and second conductive bridge structure 222 and 224 and the respective electrode may be at the central position of the respective electrode, and may have a stripe shape extending in the y-direction. In some embodiments, first electrode 212 and second electrode 216 have the same length (e.g., L) in the x-direction and are aligned with each other vertically (e.g., in the z-direction). The central positions (e.g., at L/2) of first electrode 212 and second electrode 216 align with each other in the z-direction. For example, first conductive bridge structure 222 and second conductive bridge structure 224 may be aligned at and be in contact with the respective electrode at the L/2 location.

In some embodiments, although not shown, first electrode 212 (or second layer 212-2) and second electrode 216 (or second layer 216-2) may each be in contact with a material of low acoustic impedance, such as silicon oxide and/or air. For example, silicon oxide may surround a respective conductive bridge structure (222/224), and be in contact with the respective electrode (212/216).

In some embodiments, the vertical projections of first conductive bridge 222 and/or second conductive bridge 224 may overlap with the overlapping area between first electrode 212 and second electrode 216. That is, the vertical projections (e.g., the stripe shape) of first conductive bridge 222 and/or second conductive bridge 224 may overlap with the resonating area of BAW structure 230. To reduce or minimize acoustic loading and/or mechanical loading on the resonating area, first conductive bridge structure 222 and second conductive bridge structure 224 may each include a stack of alternating low/high acoustic impedance metal layers in the respective vertical portion in contact with the respective electrode. As shown in FIG. 2D, first conductive bridge structure 222 may include a stack structure 218 in contact with first electrode 212 (or 212-2) and in contact with a metal layer 219, and second conductive bridge structure 224 may include a stack structure 220 in contact with second electrode 216 (or 216-2) and in contact with a metal layer 221. Stack structure 218 can exhibit similar acoustic properties as the material (e.g., silicon oxide and/or air) surrounding/in contact with the first and second electrodes 212 and 216 (or the resonating area of BAW structure 230), thus minimizing the acoustic loading and/or mechanic loading on the resonating area at the contact area (e.g., stripe shape) between the respective conductive bridge structure (e.g., 222 or 224) and the electrode.

Stack structure 218 may include one or more first stack layers 218-1 and one or more second stack layers 218-2 stacking alternatingly in the z-direction. First stack layer 218-1 and second stack layer 218-2 may include materials of low resistance (e.g., high conductivity) and different acoustic impedance. In some embodiments, first stack layer 218-1 includes metal of high acoustic impedance, and second stack layer 218-2 includes metal of low acoustic impedance. For example, first stack layer 218-1 includes tungsten and second stack layer 218-2 includes aluminum copper. In some embodiments, a second stack layer 218-2 is in contact with first electrode 212. Stack structure 220 may be similar to stack structure 218 and may also include one or more first stack layers 220-1 and one or more second stack layers 220-2 stacking alternatingly in the z-direction. First stack layer 220-1 and second stack layer 220-2 may include materials of low resistance (e.g., high conductivity) and different acoustic impedance. In some embodiments, first stack layer 220-1 includes metal of high acoustic impedance, and second stack layer 220-2 includes metal of low acoustic impedance. In various embodiments, first stack layer 220-1 can be the same as or different from first stack layer 218-1, and second stack layer 220-2 can be the same as or different from second stack layer 218-2. In some embodiments, first stack layer 220-1 includes the same material as first stack layer 218-1, and second stack layer 220-2 includes the same material as second stack layer 218-2. In some embodiments, a second stack layer 220-2 is in contact with second electrode 216. In some embodiments, metal layers 219 and 221 each includes a metal material of low resistance, such as tungsten.

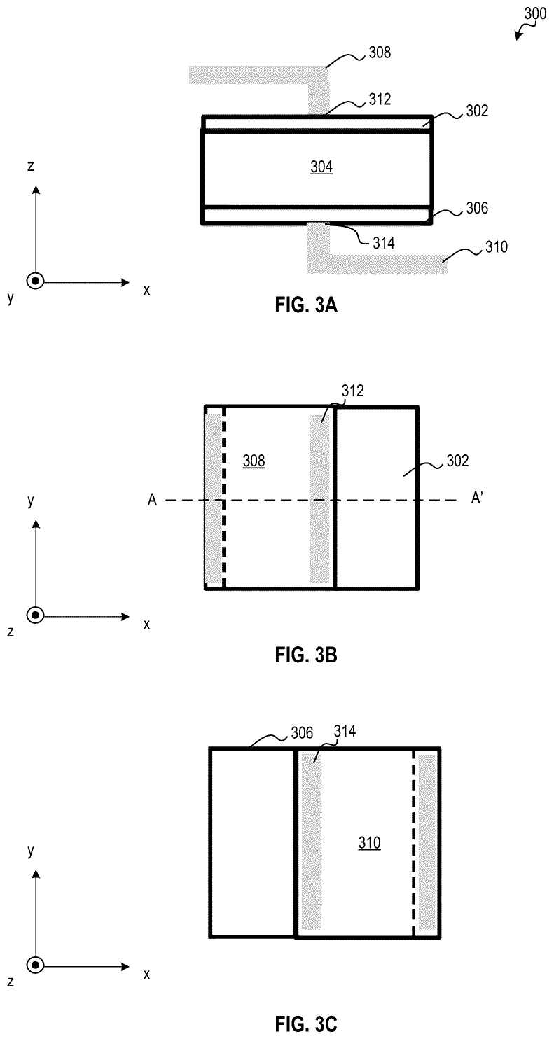

FIGS. 3A-3C, 4A-4C, and 5A-5C illustrate various exemplary BAW structures (e.g., transducers) 300, 400, and 500, according to some embodiments. Specifically, FIGS. 3A, 4A, and 5A are each a side view, FIGS. 3B, 4B, and 5B are each a top view of the respective BAW structure, and FIGS. 3C, 4C, and 5C are each a bottom view of the respective BAW structure. In some embodiments, FIGS. 3A, 4A, 5A, 6A, 7A, 8A, 10A, and 11A are respective cross-sectional views of the respective BAW structure along the A-A′ direction shown in FIGS. 3B, 4B, 5B, 6B, 7B, 8B, 10B, and 11B. BAW structures 300, 400, and 500 may each include two conductive bridge structures disposed on opposite sides, each in contact with a respective electrode. In BAW structures 300, 400, and 500, the contact areas of conductive bridge structures and the respective electrode extend in one direction, e.g., the y-direction. In some embodiments, BAW structures 300, 400, and 500 are referred to as the two-dimensional realizations of structural diagram 200/201. In some embodiments, a layer of insulating material (e.g., silicon oxide and/or air) is disposed on each electrode, e.g., in contact with the electrode and the conductive bridge structure to provide insulation and/or support. For ease of illustration, the layer of insulating material is not shown.

As shown in FIG. 3A, BAW structure 300 includes a first electrode 302, a second electrode 306, and a piezoelectric layer 304 disposed between first electrode 302 and second electrode 306. The materials of first electrode 302, second electrode 306, and piezoelectric layer 304 are respectively similar to first electrode 212, second electrode 216, and piezoelectric layer 214, and the detailed description is not repeated herein. In some embodiments, first electrode 302 and second electrode 306 have the same size, and the boundaries of first and second electrodes 302 and 306 are aligned with each other in the z-direction. In some embodiments, the resonating area of BAW structure 300 may be the same size as first and second electrodes 302 and 306.

As shown in FIGS. 3A-3C, BAW structure 300 may include a first conductive bridge structure 308 in contact with first electrode 302 at a contact area 312, and a second conductive bridge structure 310 in contact with second electrode 306 at a contact area 314. Contact areas 312 and 314, represented by the shades, may each have a stripe shape and extend in the y-direction. In some embodiments, contact areas 312 and 314 are aligned with each other in the z-direction, and may each be disposed at the central position of the respective electrode (or the resonating area of BAW structure 300) in the x-direction. First conductive bridge structure 308 and second conductive bridge structure 310 may each include a vertical portion (e.g., extending in the positive or negative z-direction) in contact with a horizontal portion (e.g., extending in the positive or negative x-direction). First conductive bridge structure 308 (e.g., the vertical portion of first conductive bridge structure 308) may extend in the z-direction from contact area 312, and (e.g., the horizontal portion of first conductive bridge structure 308) may extend in the negative x-direction towards one end of first electrode 302. The boundary of first electrode 302 is depicted in a dashed line in FIG. 3B. Second conductive bridge structure 310 (e.g., the vertical portion of second conductive bridge structure 310) may extend in the negative z-direction from contact area 314, and (e.g., the horizontal portion of second conductive bridge structure 310) may extend in the positive x-direction (e.g., the opposite direction of the negative x-direction) towards one end of second electrode 306. The boundary of second electrode 306 is depicted in a dashed line in FIG. 3C. In some embodiments, because contact areas 312 and 314 are aligned with each other and overlap with the resonating area of BAW structure 300, first conductive bridge structure 308 includes a stack structure (e.g., similar to stack structure 218) in the vertical portion in contact with first electrode 302, and second conductive bridge structure 310 includes a stack structure (e.g., similar to stack structure 220) in the vertical portion in contact with second electrode 306. The arrangement and materials of the stack structures may be referred to the description of stack structures 218 and 220, and the detailed description is not repeated herein.

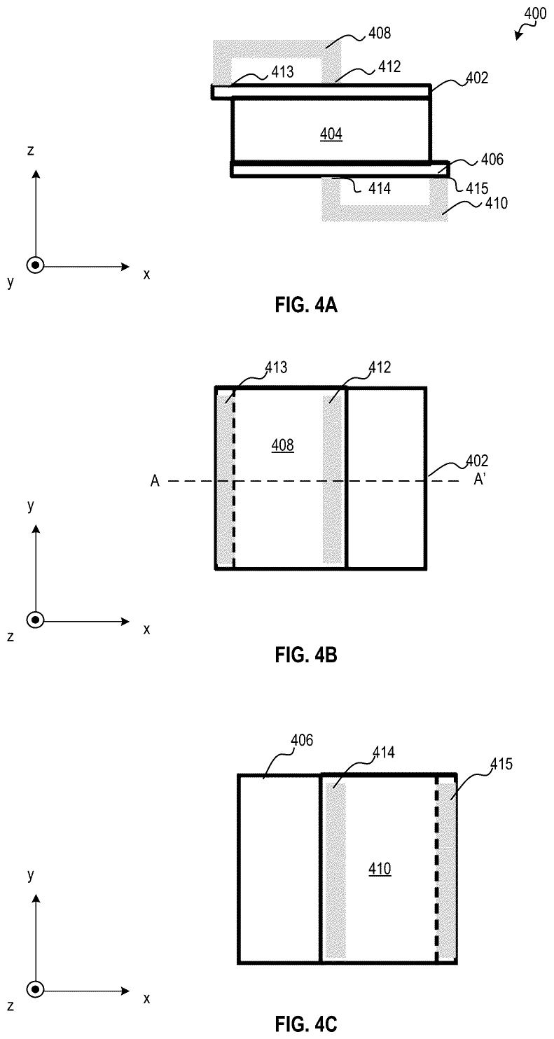

As shown in FIG. 4A, BAW structure 400 includes a first electrode 402, a second electrode 406, and a piezoelectric layer 404 disposed between first electrode 402 and second electrode 406. The materials of first electrode 402, second electrode 406, and piezoelectric layer 404 are respectively similar to first electrode 212, second electrode 216, and piezoelectric layer 214, and the detailed description is not repeated herein. In some embodiments, first electrode 302 and second electrode 306 have about the same size, and protrude from the boundary of piezoelectric layer 404 towards opposite directions (e.g., the positive and negative x-directions). In some embodiments, the resonating area of BAW structure 300 may be the same size as piezoelectric layer 404.

As shown in FIGS. 4A-4C, BAW structure 400 may include a first conductive bridge structure 408 in contact with first electrode 402 at contact areas 412 and 413, and a second conductive bridge structure 410 in contact with second electrode 406 at contact areas 414 and 415. Contact areas 412, 413, 414, and 415, represented by the shades, may each have a stripe shape and extend in the y-direction. In some embodiments, contact areas 412 and 414 are aligned with each other in the z-direction. The vertical projections of contact areas 412 and 414 may be at the central position of piezoelectric layer 404 (or the resonating area of BAW 400) in the x-direction. Contact areas 413 and 415 may be respectively at the protruding area (e.g., edge) of first electrode 402 and second electrode 406. First conductive bridge structure 408 and second conductive bridge structure 410 may each include two vertical portions (e.g., extending in the positive or negative z-direction) in contact with a horizontal portion (e.g., extending in the positive or negative x-direction). First conductive bridge structure 408 (e.g., a first vertical portion of first conductive bridge structure 408) may extend in the positive z-direction from contact area 412, (e.g., a horizontal portion of first conductive bridge structure 408) extend in the negative x-direction towards one end of first electrode 402, and (e.g., a second vertical portion of first conductive bridge structure 408) extend in the negative z-direction such that first conductive bridge structure 408 is in contact with the end of first electrode 402 at contact area 413. The boundary of piezoelectric layer 404 is depicted in a dashed line in FIG. 4B. Second conductive bridge structure 410 (e.g., a first vertical portion of second conductive bridge structure 410) may extend in the negative z-direction from contact area 414, (e.g., a horizontal portion of second conductive bridge structure 410) extend in the positive x-direction (e.g., the opposite direction of the negative x-direction) towards one end of second electrode 406, and (e.g., a second vertical portion of second conductive bridge structure 410) extend in the positive z-direction such that second conductive bridge structure 410 is in contact with the end of second electrode 406 at contact area 415. The boundary of piezoelectric layer 404 is depicted in a dashed line in FIG. 4C. In some embodiments, because contact areas 412 and 414 (e.g., first and second conductive bridge structures 408 and 410) are aligned with each other and overlap with the resonating area, first conductive bridge structure 408 includes a stack structure (e.g., similar to stack structure 218) in the first vertical portion, and second conductive bridge structure 410 includes a stack structure (e.g., similar to stack structure 220) in the first vertical portion. The arrangement and materials of the stack structures may be referred to the description of stack structures 218 and 220, and the detailed description is not repeated herein. In some embodiments, because contact areas 413 and 415 have no overlap with the resonating area, no stack structure is formed in the second vertical portions of first conductive bridge structure 408 and second conductive bridge structure 410.

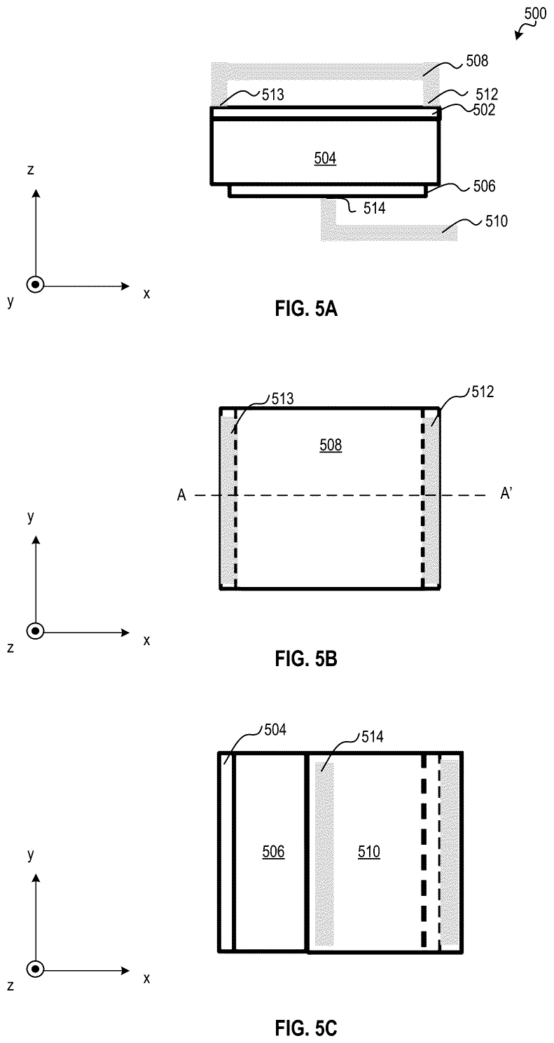

As shown in FIG. 5A, BAW structure 500 includes a first electrode 502, a second electrode 506, and a piezoelectric layer 504 disposed between first electrode 502 and second electrode 506. In some embodiments, a vertical projection of first electrode 502 exceeds a vertical projection of second electrode 506 in the negative and positive x-directions. In some embodiments, the resonating area of BAW structure 500 may have the same size as second electrode 506. The materials of first electrode 502, second electrode 506, and piezoelectric layer 504 are respectively similar to first electrode 212, second electrode 216, and piezoelectric layer 214, and the detailed description is not repeated herein.

As shown in FIGS. 5A-5C, BAW structure 500 may include a first conductive bridge structure 508 in contact with first electrode 502 at contact areas 512 and 513, and a second conductive bridge structure 510 in contact with second electrode 506 at a contact area 514. In some embodiments, contact areas 512 and 513 are located at the edges/ends of first electrode 502, and contact area 514 is located at the central position of second electrode 506 in the x-direction. Contact areas 512, 513, and 514, represented by the shades, may each have a stripe shape and extend in the y-direction. First conductive bridge structure 508 include two vertical portions (e.g., extending in the positive and negative z-directions) in contact with a horizontal portion (e.g., extending in the positive or negative x-direction). Second conductive bridge structure 510 may include a vertical portion (e.g., extending in the negative z-directions) extending from contact area 514 and in contact with a horizontal portion (e.g., extending in the positive x-direction). First conductive bridge structure 508 (e.g., a first vertical portion of first conductive bridge structure 508) may extend in the positive z-direction from contact area 512 on one end, (e.g., a horizontal portion of first conductive bridge structure 508) extend in the negative x-direction towards the other end of first electrode 502, and (e.g., a second vertical portion of first conductive bridge structure 508) extend in the negative z-direction again such that first conductive bridge structure 508 is in contact with the other end of first electrode 502 at contact area 513. The boundaries of second electrode 506 are depicted in dashed lines in FIG. 5B. Second conductive bridge structure 510 (e.g., the vertical portion of second conductive bridge structure 510) may extend in the negative z-direction from contact area 514, and (e.g., the horizontal portion of second conductive bridge structure 510) extend in the positive x-direction towards one end of second electrode 506. The boundary of second electrode 506 is depicted in the thicker dashed line in FIG. 5C, while the boundary of piezoelectric layer 504/first electrode 502 is depicted in the thinner dashed line in FIG. 5C. In some embodiments, contact areas 512 and 513 are each not aligned with contact area 514 in the z-direction. The vertical projections of contact areas 512 and 513 may each have zero or little overlap with second electrode 506. In some embodiments, because contact areas 512 and 513 (e.g., first conductive bridge structure 508) have no overlap with the resonating area, no stack structure (e.g., similar to stack structure 218) is formed in first conductive bridge structure 508. In some embodiments, contact area 514 (e.g., second conductive bridge structure 510) overlaps with the resonating area, a stack structure (e.g., similar to stack structure 218) may be formed in second conductive bridge structure 510.

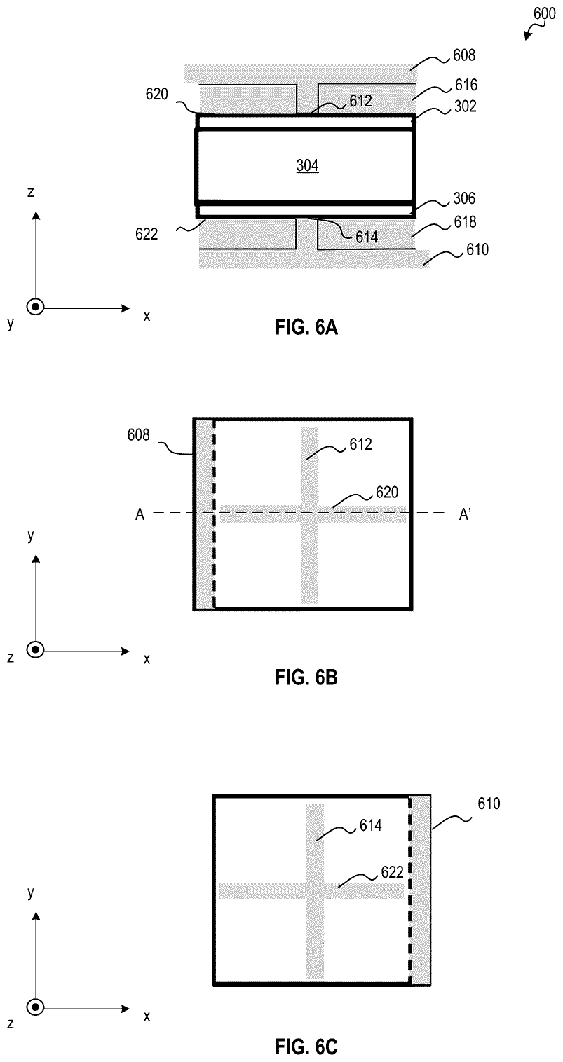

FIGS. 6A-6C, 7A-7C, and 8A-8C illustrate various exemplary BAW structures (e.g., transducers) 600, 700, and 800, according to some embodiments. Specifically, FIGS. 6A, 7A, and 8A are each a side view, FIGS. 6B, 7B, and 8B are each a top view of the respective BAW structure, and FIGS. 6C, 7C, and 8C are each a bottom view of the respective BAW structure. BAW structures 600 and 700 may each include four conductive bridge structures disposed on opposite sides, with each electrode in contact with two of the conductive bridge structures. BAW structure 800 may include three conductive bridge structures, with one in contact with one of the electrodes, and the other two in contact with the other electrode. In BAW structures 600, 700, and 800, the contact areas between conductive bridge structures and the respective electrode extend in two directions, e.g., the x-direction and the y-direction. In some embodiments, BAW structures 600, 700, and 800 are referred to as the three-dimensional realizations of structural diagram 200/201. In some embodiments, a layer of insulating material (e.g., silicon oxide and/or air) is disposed on each electrode, e.g., in contact with the electrode and the conductive bridge structure(s) to provide insulation and/or support. For case of illustration, the layer of insulating material is not shown.

As shown in FIG. 6A, BAW structure 600 includes first electrode 302, second electrode 306, and piezoelectric layer 304 disposed between first electrode 302 and second electrode 306. As shown in FIGS. 6A-6C, BAW structure 600 may include a first conductive bridge structure 608 in contact with first electrode 302 at a contact area 612, and a second conductive bridge structure 610 in contact with second electrode 306 at a contact area 614. Contact areas 612 and 614, represented by the shades, may each have a stripe shape and extend in the y-direction. In some embodiments, contact areas 612 and 614 are aligned with each other in the z-direction. In some embodiments, contact areas 612 and 614 are at the central position of the respective electrode e.g., in the x-direction. First conductive bridge structure 608 and second conductive bridge structure 610 may each include a vertical portion (e.g., extending in the positive or negative z-direction) in contact with a horizontal portion (e.g., extending in the positive and negative x-directions). First conductive bridge structure 608 (e.g., the vertical portion of first conductive bridge structure 608) may extend in the z-direction from contact area 612, and (e.g., the horizontal portion of second conductive bridge structure 610) may extend in the positive and negative x-directions towards the ends of first electrode 302. The boundary of first electrode 302 is depicted as the dashed line in FIG. 6B. Second conductive bridge structure 610 (e.g., the vertical portion of second conductive bridge structure 610) may extend in the z-direction from contact area 614, and (e.g., the horizontal portion of second conductive bridge structure 610) may extend in the positive and negative x-directions towards the ends of second electrode 306. The boundary of second electrode 306 is depicted as the dashed line in FIG. 6C.

BAW structure 600 may further include a third conductive bridge structure 616 in contact with first electrode 302 at a contact area 620, and a fourth conductive bridge structure 618 in contact with second electrode 306 at a contact area 622. Contact areas 620 and 622, represented by the shades, may each have a stripe shape and extend in the x-direction. In some embodiments, contact areas 620 and 622 are aligned with each other in the z-direction. In some embodiments, contact areas 620 and 622 are at the central position of the respective electrode e.g., in the y-direction. Third conductive bridge structure 616 and fourth conductive bridge structure 618 may each include a vertical portion (e.g., extending in the positive or negative z-direction) in contact with a horizontal portion (e.g., extending in the positive and negative y-directions). Third conductive bridge structure 616 (e.g., the vertical portion of third conductive bridge structure 616) may extend in the positive z-direction from contact area 620, and (e.g., the horizontal portion of third conductive bridge structure 616) may extend in the positive and negative y-directions. Fourth conductive bridge structure 618 (e.g., the vertical portion of fourth conductive bridge structure 618) may extend in the negative z-direction from contact area 622, and (e.g., the horizontal portion of fourth conductive bridge structure 618) may extend in the positive and negative y-directions. In some embodiments, first and third conductive bridge structures 608 and 616 share the same horizontal portion. In some embodiments, second and fourth conductive bridge structures 610 and 618 share the same horizontal portion.

Contact area 612 may intersect with contact area 620, and contact area 614 may intersect with contact area 622. In some embodiments, because contact areas 612, 614, 620, and 622 overlap with the resonating area, first and third conductive bridge structures 608 and 616 each includes a stack structure (e.g., similar to stack structure 218) in the respective vertical portion, and second and fourth conductive bridge structures 610 and 618 each includes a stack structure (e.g., similar to stack structure 220) in the respective vertical portion. The arrangement and materials of the stack structures may be referred to the description of stack structures 218 and 220, and the detailed description is not repeated herein.

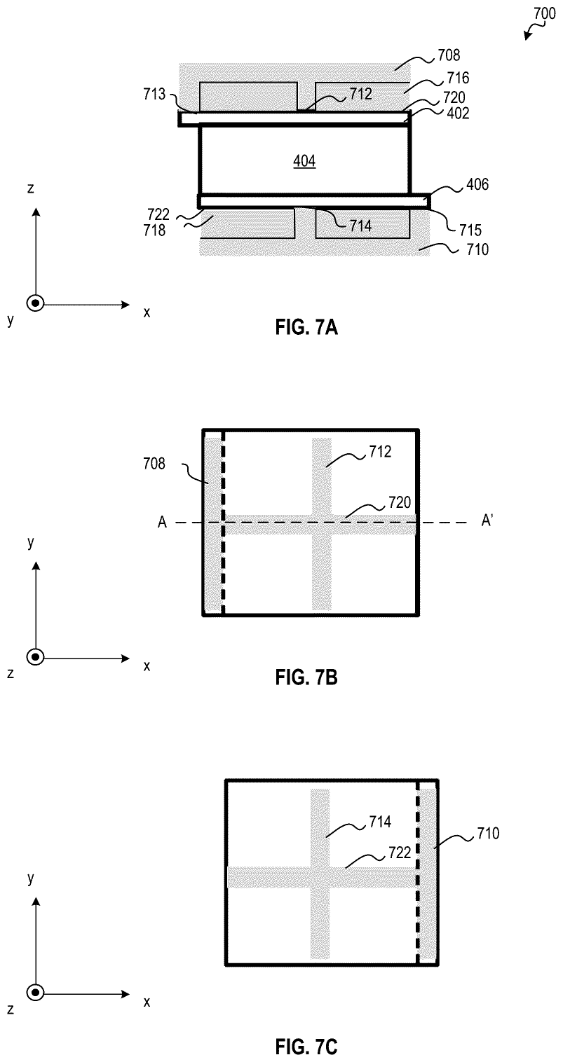

As shown in FIG. 7A, BAW structure 700 includes first electrode 402, second electrode 406, and piezoelectric layer 404 disposed between first electrode 402 and second electrode 406. As shown in FIGS. 7A-7C, BAW structure 700 may include a first conductive bridge structure 708 in contact with first electrode 402 at contact areas 712 and 713, and a second conductive bridge structure 710 in contact with second electrode 406 at contact areas 714 and 715. The vertical projections of contact areas 712 and 714 may each be located at the central position of the resonating area (e.g., piezoelectric layer 404) in the x-direction. Contact areas 713 and 715 may respectively be located at the protruding area (e.g., edge) of the respective electrode such that the vertical projections of contact areas 713 and 715 do not overlap with the second electrode 406. Contact areas 712, 713, 714, and 715, represented by the shades, may each have a stripe shape and extend in the y-direction. In some embodiments, contact areas 712 and 714 are aligned with each other in the z-direction. First conductive bridge structure 708 and second conductive bridge structure 710 may each include two vertical portions (e.g., extending in the positive or negative z-direction) in contact with a horizontal portion (e.g., extending in the positive and negative x-directions). First conductive bridge structure 708 (e.g., a first vertical portion and a second vertical portion of first conductive bridge structure 708) may extend in the positive z-direction from contact areas 712 and 713, respectively, and (e.g., the horizontal portion of first conductive bridge structure 408) extend in the positive and negative x-directions. The boundary of piezoelectric layer 404 is depicted in a dashed line in FIG. 7B. Second conductive bridge structure 710 (e.g., a first vertical portion and a second vertical portion of second conductive bridge structure 710) may extend in the negative z-direction from contact areas 714 and 715, respectively, and (e.g., the horizontal portion of second conductive bridge structure 710) extend in the positive and negative x-directions. The boundary of piezoelectric layer 404 is depicted in a dashed line in FIG. 7C.

In some embodiments, because the vertical projections of contact areas 712 and 714 overlap with that of the resonating area (or piezoelectric layer 404), first conductive bridge structure 708 includes a stack structure (e.g., similar to stack structure 218) in the first vertical portion, and second conductive bridge structure 410 includes a stack structure (e.g., similar to stack structure 220) in the first vertical portion. The arrangement and materials of the stack structures may be referred to the description of stack structures 218 and 220, and the detailed description is not repeated herein. In some embodiments, because the vertical projections of contact areas 713 and 715 have no overlap with that of the resonating area (e.g., piezoelectric layer 404), no stack structure is formed in the second vertical portions of first conductive bridge structure 708 and second conductive bridge structure 710.

BAW structure 700 may further include a third conductive bridge structure 716 in contact with first electrode 402 at a contact area 720, and a fourth conductive bridge structure 718 in contact with second electrode 406 at a contact area 722. Contact areas 720 and 722, represented by the shades, may each have a stripe shape and extend in the x-direction. In some embodiments, contact areas 720 and 722 are aligned with each other in the z-direction. In some embodiments, contact areas 720 and 722 are each at the central position of the respective electrode in the y-direction. Third conductive bridge structure 716 and fourth conductive bridge structure 718 may each include a vertical portion (e.g., extending in the positive or negative z-direction) in contact with a horizontal portion (e.g., extending in the positive and negative y-directions). Third conductive bridge structure 716 (e.g., the vertical portion of third conductive bridge structure 716) may extend in the positive z-direction from contact area 720, and (e.g., the horizontal portion of third conductive bridge structure 716) may extend in the positive and negative y-directions. Fourth conductive bridge structure 718 (e.g., the vertical portion of fourth conductive bridge structure 718) may extend in the negative z-direction from contact area 722, and (e.g., the horizontal portion of fourth conductive bridge structure 718) may extend in the positive and negative y-directions. In some embodiments, first and third conductive bridge structures 708 and 716 share the same horizontal portion. In some embodiments, second and fourth conductive bridge structures 710 and 718 share the same horizontal portion.

Contact area 712 may intersect with contact area 720, and contact area 714 may intersect with contact area 722. In some embodiments, because contact areas 720 and 722 overlap with the resonating area (e.g., piezoelectric layer 404), third conductive bridge structures 716 includes a stack structure (e.g., similar to stack structure 218) in the respective vertical portion, and fourth conductive bridge structures 718 includes a stack structure (e.g., similar to stack structure 220) in the respective vertical portion. The arrangement and materials of the stack structures may be referred to the description of stack structures 218 and 220, and the detailed description is not repeated herein.

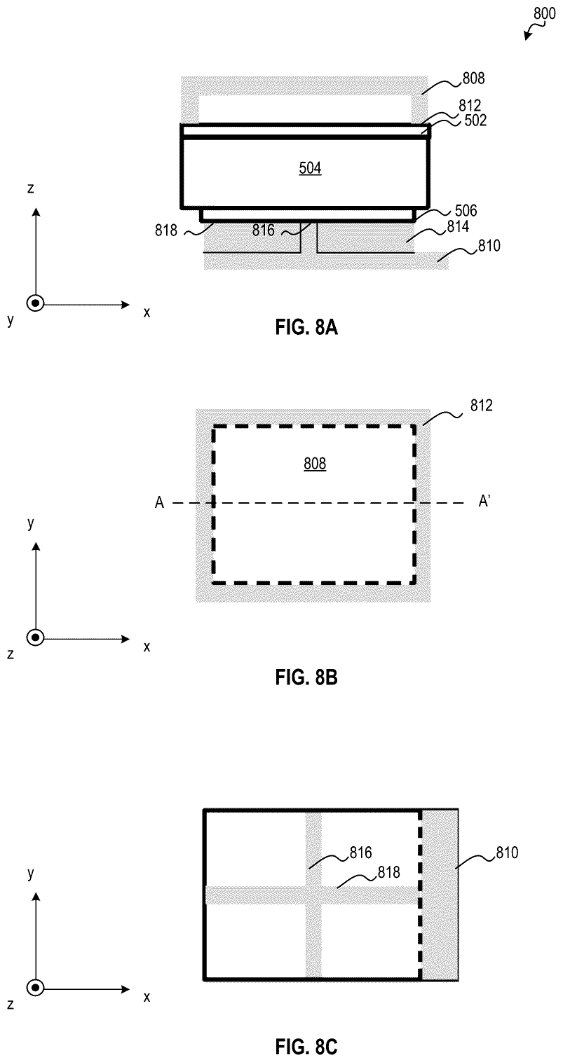

As shown in FIG. 8A, BAW structure 800 includes first electrode 502, second electrode 506, and piezoelectric layer 504 disposed between first electrode 502 and second electrode 506. As shown in FIGS. 8A-8C, BAW structure 800 may include a first conductive bridge structure 808 in contact with first electrode 502 at a contact area 812, a second conductive bridge structure 810 in contact with second electrode 506 at a contact area 816, and a third conductive bridge structure 814 in contact with second electrode 506 at a contact area 818. Contact areas 812, 814, and 818 are represented by the shades. Contact area 816 may be at the central position of second electrode 506 in the x-direction, and contact area 818 may be at the central position of second electrode 506 in the y-direction. Contact area 812 may be distributed on the peripheral area (e.g., edge) of first electrode 502 and may form an enclosure. In some embodiments, a vertical projection of contact area 812 may not be in contact with a vertical projection of second electrode 506 such that the resonating area (e.g., the overlapping area between first and second electrodes 502 and 506) has little or no contact with contact area 812. The boundary of contact area 812 is depicted in dashed lines in FIG. 8B. Contact area 816 may have a stipe shape and extend in the y-direction, and contact area 818 may have a stripe shape and extend in the x-direction. In some embodiments, contact area 816 intersects with contact area 818.

First conductive bridge structure 808 include a vertical portion (e.g., extending in the positive or negative z-direction) in contact with a horizontal portion (e.g., extending in the positive or negative x-direction). First conductive bridge structure 808 (e.g., the vertical portion of first conductive bridge structure 808) may extend from contact area 812 and be in contact with the horizontal portion that cover the rest of first electrode 502. Second conductive bridge structure 810 and third conductive bridge structure 814 may each include a vertical portion (e.g., extending in the negative z-directions) in contact with a horizontal portion (e.g., extending in the x-direction or y-direction). Second conductive bridge structure 810 (e.g., the vertical portion of second conductive bridge structure 810) may vertically extend from contact area 816 in the negative z-direction, and (e.g., the horizontal portion of second conductive bridge structure 810) extend horizontally in the positive and negative x-directions. Third conductive bridge structure 814 (e.g., the vertical portion of third conductive bridge structure 814) may vertically extend from contact area 818 in the negative z-direction, and (e.g., the horizontal portion of third conductive bridge structure 814) extend horizontally in the positive and negative y-directions. The boundary of second electrode 506 is depicted as the dashed line in FIG. 8C. In some embodiments, because contact area 812 has no overlap within the resonating area, no stack structure (e.g., similar to stack structure 220) is formed in first conductive bridge structure 808. In some embodiments, contact area 816 and 818 each overlaps with the resonating area, a stack structure (e.g., similar to stack structure 220) is formed in each of second and third conductive bridge structures 810 and 814.

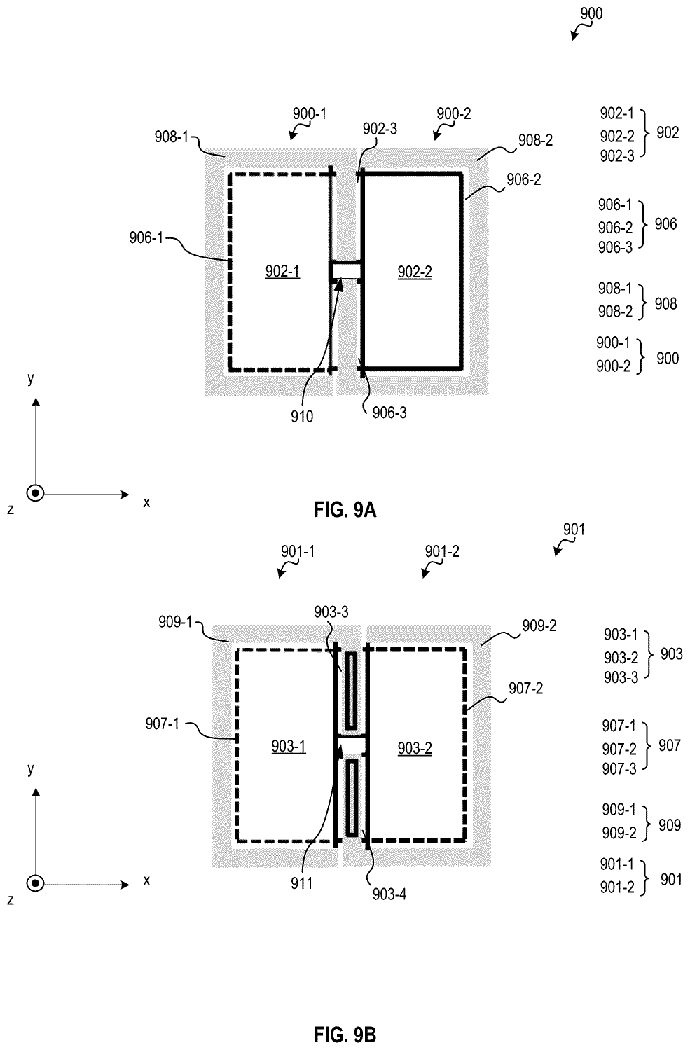

FIG. 9A shows a top view of an exemplary BAW structure (e.g., a transducer) 900, according to some embodiments. BAW structure 900 may include a first electrode 902, a second electrode 906, and a piezoelectric layer (not shown for case of illustration) between first electrode 902 and second electrode 906. A conductive bridge structure 908 (or a conductive structure) may include two electrically disconnected portions 908-1 and 908-2, which may be in contact with BAW structure 900 at the central positions of first electrode 902 and second electrode 906, respectively. In some embodiments, a gap 910 separates portions 908-1 and 908-2 in the y-direction. Conductive bridge structure 908 may be disposed in the same plane or parallel planes. BAW structure 900 may be referred to as a planar BAW structure. As an example, first electrode 902 is shown on top of second electrode 906.

As shown in FIG. 9A, first electrode 902 may include a first electrode portion 902-1, a second electrode portion 902-2, and a central portion 902-3 connecting first electrode portion 902-1 and second electrode portion 902-2; and second electrode 906 may include a first electrode portion 906-1, a second electrode portion 906-2, and a central portion 906-3 connecting first electrode portion 906-1 and second electrode portion 906-2. In some embodiments, in the z-direction, vertical projections of first electrode portions 902-1 and 906-1 may partially overlap with each other, vertical projections of second electrode portions 902-2 and 906-2 may partially overlap with each other, and vertical projections of central portions 902-3 and 906-3 has no overlap. Central portions 902-3 and 906-3 may have the same or similar size and shape. As an example, in the y-direction, central portion 902-3 is located in the upper portion of BAW structure 900, and central portion 906-3 is located in the lower portion of BAW structure 900. In some embodiments, first electrode portion 902-1 is larger than first electrode portion 906-1 such that a boundary of first electrode portion 902-1 exceeds a boundary of first electrode portion 906-1 in the x-y plane. The boundary of first electrode portion 906-1, covered by first electrode portion 902-1, is shown as the dashed line in FIG. 9A. In some embodiments, second electrode portion 902-2 is smaller than second electrode portion 906-2 such that a boundary of second electrode portion 906-2 exceeds a boundary of second electrode portion 902-2 in the x-y plane. The boundary of second electrode portion 902-2, exposed by second electrode portion 906-2, is shown as the solid line in FIG. 9A. In some embodiments, the overlapping area of first electrode portions 902-1 and 906-1, and the portion of piezoelectric layer in between form a resonating area in a first sub-transducer 900-1; and the overlapping area of second electrode portions 902-2 and 906-2, and the portion of piezoelectric layer in between form another resonating area in a second sub-transducer 900-2.

Conductive bridge structure 908 may include a first bridge portion 908-1 in contact with central portion 902-3 and surrounding and in contact with a peripheral area of first electrode portion 902-1, and a second bridge portion 908-2 (electrically disconnected from the first bridge portion 908-1) in contact with central portion 906-3 and surrounding and in contact with a peripheral area of second electrode portion 906-2. As shown in FIG. 9A, because the boundary of first electrode portion 902-1 exceeds that of first electrode portion 906-1, the boundary of second electrode portion 906-2 exceeds that of second electrode portion 902-2, and central portions 902-3 and 906-3 has no overlap, no overlap is formed between conductive bridge structure 908 and the resonating areas of BAW structure 900. In some embodiments, no stack structure (similar to stack structures 218 or 220) is formed in conductive bridge structure 908. In some embodiments, first bridge portion 908-1 and second bride portion 908-2 may be disposed in parallel planes. For example, first bridge portion 908-1 may be disposed in the same plane as first electrode portion 902-1, and second bridge portion 908-2 may be disposed in the same plane as second electrode portion 906-2. In some embodiments, first bridge portion 908-1 and second bridge portion 908-2 are disposed in the same plane, in which case a conductive via in the piezoelectric is used to connect one bridge portion to its respective electrode portion. For example, if the bridge structure 908 is disposed in the plane of electrode portion 902-1, a conductive via in the piezoelectric is used to connect the bridge portion 908-2 to the electrode portion 906-2.

In some embodiments, the materials of first electrode 902, second electrode 906, the piezoelectric layer, and conductive bridge structure 908 are similar to their counterparts in BAW structure 230, and the detailed description is not repeated herein.

FIG. 9B shows a top view of another exemplary BAW structure (e.g., a transducer) 901, according to some embodiments. BAW structure 901 may include a first electrode 903, a second electrode 907, and a piezoelectric layer (not shown for ease of illustration) between first electrode 903 and second electrode 907. As an example, first electrode 903 is shown on top of second electrode 907.

As shown in FIG. 9B, first electrode 903 may include a first electrode portion 903-1, a second electrode portion 903-2, a central portion 903-3 in contact with first electrode portion 903-1, and a central portion 903-4 in contact with second electrode portion 903-2. Electrode portions 903-1 and 903-2 are electrically disconnected. In some embodiments, a gap 911 separates portions 909-1 and 909-2 in the y-direction. In some embodiments, in the z-direction, vertical projections of first electrode portions 903-1 and 907-1 may partially overlap with each other, vertical projections of first electrode portions 903-2 and 907-2 may partially overlap with each other, and vertical projections of central portions 903-3 and 903-4 has no overlap. Central portions 903-3 and 903-4 may have the same or similar size and shape. As an example, in the y-direction, central portion 903-3 is located in the upper portion of BAW structure 901, and central portion 903-4 is located in the lower portion of BAW structure 901. In some embodiments, first electrode portion 907-1 and second electrode portion 907-2 are disconnected. In some embodiments, first electrode portion 903-1 is larger than first electrode portion 907-1 such that a boundary of first electrode portion 903-1 exceeds a boundary of first electrode portion 907-1 in the x-y plane. In some embodiments, second electrode portion 903-2 is larger than second electrode portion 907-2 such that a boundary of second electrode portion 903-2 exceeds a boundary of second electrode portion 907-2 in the x-y plane. The boundaries of first electrode portion 907-1 and second electrode portion 907-2, respectively covered by first electrode portion 903-1 and second electrode portion 903-2, are shown as the dashed lines in FIG. 9B. In some embodiments, the overlapping area of first electrode portions 903-1 and 907-1, and the portion of piezoelectric layer in between form a resonating area in a first sub-transducer 901-1; and the overlapping area of second electrode portions 903-2 and 907-2, and the portion of piezoelectric layer in between form another resonating area in a second sub-transducer 901-2. In some embodiments, first electrode portion 903-1 is electrically connected to second electrode portion 907-2, and first electrode portion 907-1 is electrically connected to second electrode portion 903-2.

A conductive bridge structure 909 may include a first bridge portion 909-1 in contact with central portion 903-3 and surrounding and in contact with a peripheral area of first electrode portion 903-1, and a second bridge portion 909-2 in contact with central portion 903-4 and surrounding and in contact with a peripheral area of second electrode portion 903-2. As shown in FIG. 9B, because the boundary of first electrode portion 903-1 exceeds that of first electrode portion 907-1, and the boundary of second electrode portion 903-2 exceeds that of second electrode portion 907-2, no overlap is formed between conductive bridge structure 909 and the resonating areas of BAW structure 901. In some embodiments, no stack structure (similar to stack structures 218 or 220) is formed in conductive bridge structure 909. In some embodiments, first bridge portion 909-1 and second bride portion 909-2 may be disposed in parallel planes. In some embodiments, first bridge portion 909-1 and second bridge portion 909-2 are disposed in the same plane, e.g., the same plane in which first electrode 903 is disposed, in which case the bridge structure 909 may be referred to as a planar conductive bridge structure.

In some embodiments, the materials of first electrode 903, second electrode 907, the piezoelectric layer, and conductive bridge structure 909 are similar to their counterparts in BAW structure 230, and the detailed description is not repeated herein.

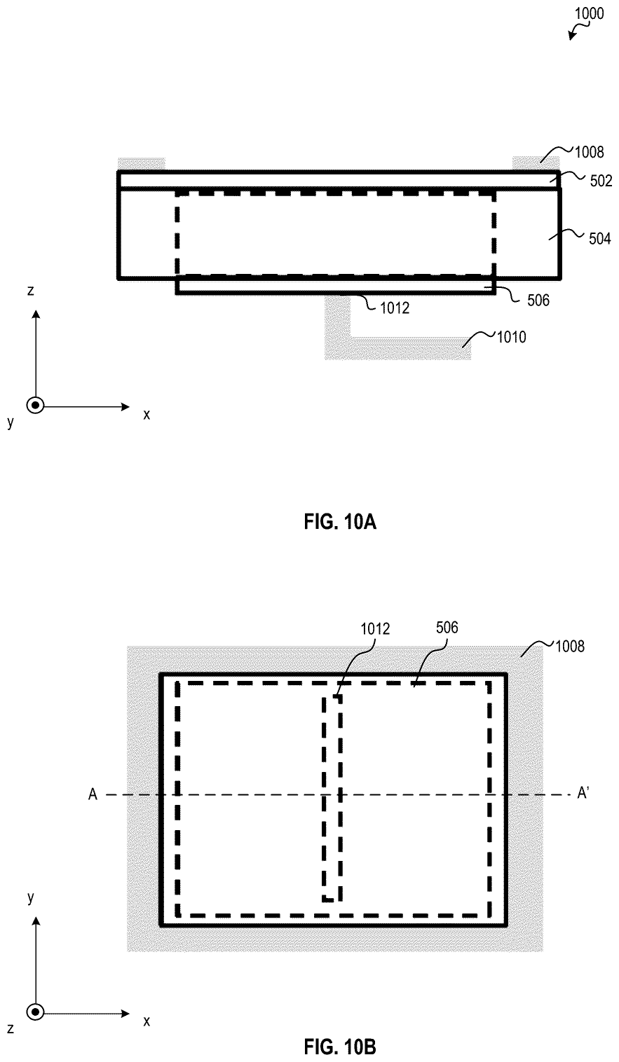

FIG. 10A illustrates a side view of another exemplary BAW structure (e.g., transducer) 1000, and FIG. 10B illustrates a top view of BAW structure 1000, according to some embodiments. As shown in FIGS. 10A and 10B, BAW structure 1000 may include a first conductive structure 1008 (e.g., a conductive bridge structure or a conductive ring structure) disposed on the peripheral area of first electrode 502, and a second conductive bridge structure 1010 in contact with second electrode 506 at a contact area 1012 located at the central position of second electrode 506. In some embodiments, contact area 1012 has a stripe shape and extends in the y-direction. First conductive structure 1008 may be disposed in the same plane (e.g., the same plane as first electrode 502), and may be referred to as a planar conductive bridge structure. In some embodiments, the vertical projection of first conductive structure 1008 surrounds the vertical projection of second electrode 506 such that little or no overlap is formed between the vertical projections of first conductive structure 1008 and second electrode 506. As shown in FIG. 10A, a resonating area is formed in the portion of piezoelectric layer 504 between the overlapped portions of first electrode 502 and second electrode 506. As shown in FIGS. 10A and 10B, no overlap is formed between first conductive structure 1008 and second conductive bridge structure 1010 in the resonating area (e.g., depicted in dashed lines) of BAW structure 1000. In some embodiments, no stack structure (e.g., similar to stack structure 218 or 220) is formed in first conductive structure 1008. In some embodiments, a stack structure (e.g., similar to stack structure 218 or 220) is formed in second conductive bridge structure 1010.

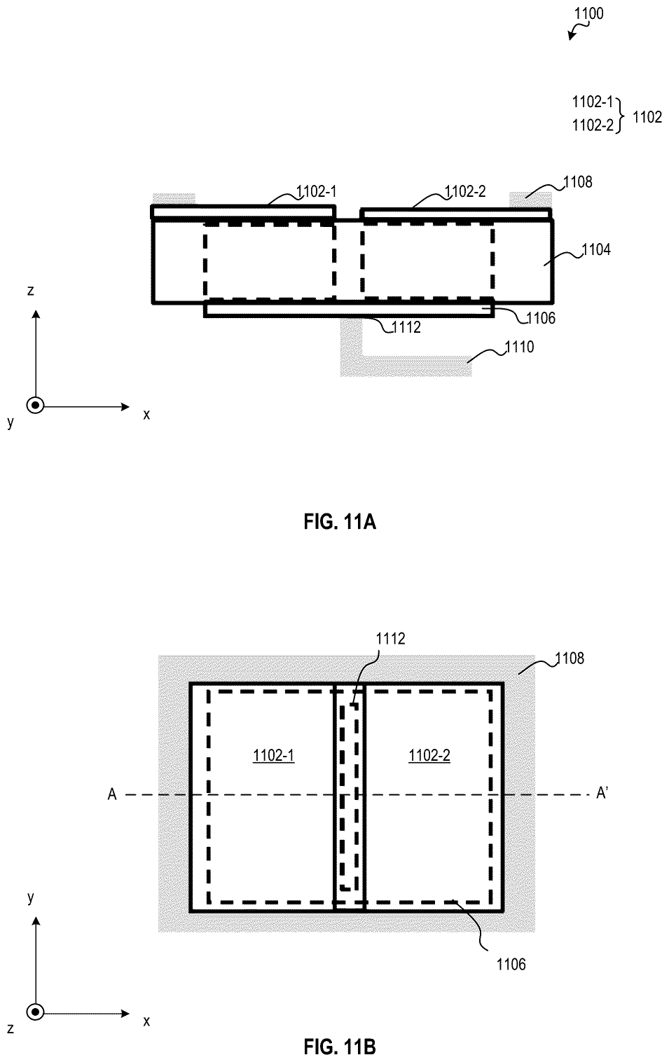

FIG. 11A illustrates a side view of another exemplary BAW structure (e.g., transducer) 1100, and FIG. 11B illustrates a top view of BAW structure 1100, according to some embodiments. BAW structure 1100 may include a first electrode 1102 and a second electrode 1106. First electrode 1102 may be larger than second electrode 1106 such that the vertical projection of first electrode 1102 exceeds the vertical projection of second electrode 1106 in the x-y plane. First electrode 1102 may include a first electrode portion 1102-1 and a second electrode portion 1102-2, separated from each other by a non-zero spacing in the x-direction. The vertical projection of the spacing may be located at the central area of second electrode 1106.

As shown in FIGS. 11A and 11B, BAW structure 1100 may include a first conductive structure 1108 (e.g., a conductive bridge structure or a conductive ring structure) disposed on the peripheral area of first electrode 1102, and a second conductive bridge structure 1110 in contact with second electrode 1106 at a contact area 1112 located at the central position of second electrode 1106. In some embodiments, contact area 1112 has a stripe shape and extends in the y-direction. In some embodiments, the vertical projection of the space fully covers contact area 1112. First conductive structure 1108 may be disposed in the same plane (e.g., the same plane as first electrode 1102), and may be referred to as a planar conductive bridge structure. In some embodiments, the vertical projection of first conductive structure 1108 surrounds the vertical projection of second electrode 1106 such that little or no overlap is formed between the vertical projections of first conductive structure 1108 and second electrode 1106. As shown in FIG. 11A, a resonating area (e.g., depicted in dashed lines) is formed between the overlapped portions of first electrode portion 1102-1 and second electrode 1106, and the portion of piezoelectric layer in between; and another resonating area (e.g., depicted in dashed lines) is formed between the overlapped portions of second electrode portion 1102-2 and second electrode 1106, and the portion of piezoelectric layer in between. In some embodiments, no overlap is formed between first conductive structure 1108 and second conductive bridge structure 1110 in the resonating areas of BAW structure 1100. In some embodiments, no stack structure (e.g., similar to stack structure 218 or 220) is formed in first conductive structure 1108 or second conductive bridge structure 1110.

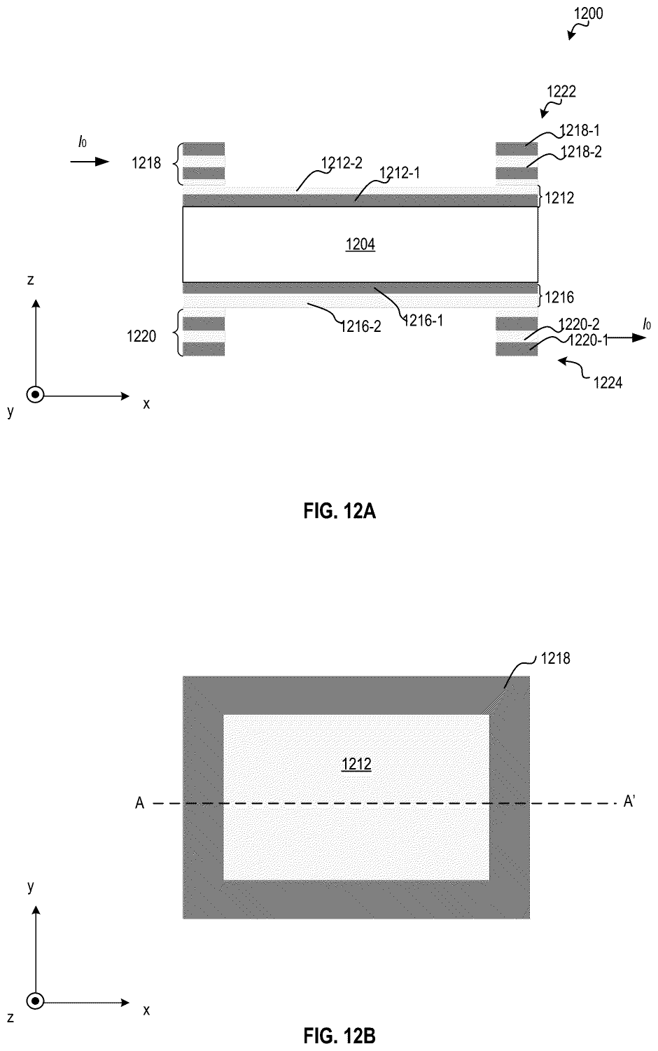

FIGS. 12A and 12B illustrate another BAW structure 1200, a transducer, with reduced electrical losses, according to some embodiments.

BAW structure 1200 may include a first electrode 1212, a second electrode 1216, and a piezoelectric layer 1204 between first electrode 212 and second electrode 1216. First electrode 1212 may include one or more suitable conductive materials, and may be a single-layer structure or a multi-layer structure. For example, first electrode 1212 may include one or more of copper (Cu), tungsten (W), aluminum copper (AlCu), molybdenum (Mo), and/or platinum (Pt). In some embodiments, first electrode 1212 includes a first layer 1212-1 in contact of piezoelectric layer 1204 on one side of piezoelectric layer 1204, and a second layer 1212-2 over and in contact with first layer 1212-1. In some embodiments, second electrode 1216 is similar to first electrode 1212, and includes a first layer 1216-1 in contact of piezoelectric layer 1204 on the other side of piezoelectric layer 1204, and a second layer 1216-2 over and in contact of first layer 1216-1. In some embodiments, first layers 1212-1 and 1216-1 each includes tungsten, and second layers 1212-2 and 1216-2 each includes aluminum copper. Piezoelectric layer 1204 may include a suitable piezoelectric material such as aluminum nitride (AlN), zinc oxide (ZnO), aluminum scandium nitride (AlScN) and/or other suitable materials.

BAW structure 1200 may include a first conductive bridge structure 1222 electrically connected to (e.g., in contact with) first electrode 1212, and a second conductive bridge structure 1224 electrically connected to (e.g., in contact with) second electrode 1216. First conductive bridge structure 1222 and second conductive bridge 1224 may be biased to conduct electrical current. First conductive bridge structure 1222 and second conductive bridge structure 1224 may each include highly conductive materials such as metals. In some embodiments, first conductive bridge structure 1222 and second conductive bridge structure 1224 may each be in contact with the respective electrode at the peripheral area of the respective electrode. Bias may be applied on first conductive bridge structure 1222 and second conductive bridge structure 1224. FIG. 12A shows an example direction where electric current Io flows into and out of the transducer. As shown in FIG. 12B, first conductive bridge structure 1222 and second conductive bridge structure 1224 may each form a “peripheral ring” contacting the respective electrode in the x-and y-directions (e.g., having stripe shapes), while exposing a central area of the respective electrode. In some embodiments, first and second conductive bridge structures 1222 and 1224 are aligned in the z-direction. In some embodiments, first electrode 1212 and second electrode 1216 have the same dimensions in the x-and y-directions.

In some embodiments, although not shown, first electrode 1212 (or second layer 1212-2) and second electrode 1216 (or second layer 1216-2) may each be in contact with a material of low acoustic impedance, such as silicon oxide and/or air. For example, silicon oxide may surround a respective conductive bridge structure (1222/1224), and be in contact with the respective electrode (1212/1216).

In some embodiments, the vertical projections of first conductive bridge 1222 and/or second conductive bridge 1224 may overlap with the overlapping area between first electrode 1212 and second electrode 1216. That is, the vertical projections of first conductive bridge 1222 and/or second conductive bridge 1224 may overlap with the resonating area of BAW structure 1200. To reduce or minimize acoustic loading and/or mechanical loading on the resonating area, first conductive bridge structure 1222 and second conductive bridge structure 1224 may each include a stack of alternating low/high acoustic impedance metal layers in the respective vertical portion in contact with the respective electrode. As shown in FIG. 12A, first conductive bridge structure 1222 may include a stack structure 1218 in contact with first electrode 1212 (or 1212-2) and in contact with a metal layer (not shown), and second conductive bridge structure 1224 may include a stack structure 1220 in contact with second electrode 1216 (or 1216-2) and in contact with another metal layer (not shown). Stack structure 1218 can exhibit similar acoustic properties as the material (e.g., silicon oxide and/or air) surrounding/in contact with the first and second electrodes 1212 and 1216 (or the resonating area of BAW structure 1200), thus minimizing the acoustic loading and/or mechanic loading on the resonating area at the contact area (e.g., the peripheral area) between the respective conductive bridge structure (e.g., 1222 or 1224) and the electrode.

Stack structure 1218 may include one or more first stack layers 1218-1 and one or more second stack layers 1218-2 stacking alternatingly in the z-direction. First stack layer 1218-1 and second stack layer 1218-2 may include materials of low resistance (e.g., high conductivity) and different acoustic impedance. In some embodiments, first stack layer 1218-1 includes metal of high acoustic impedance, and second stack layer 1218-2 includes metal of low acoustic impedance. For example, first stack layer 1218-1 includes tungsten and second stack layer 1218-2 includes aluminum copper. In some embodiments, a second stack layer 1218-2 is in contact with first electrode 1212. Stack structure 1220 may be similar to stack structure 1218 and may also include one or more first stack layers 1220-1 and one or more second stack layers 1220-2 stacking alternatingly in the z-direction. First stack layer 1220-1 and second stack layer 1220-2 may include materials of low resistance (e.g., high conductivity) and different acoustic impedance. In some embodiments, first stack layer 1220-1 includes metal of high acoustic impedance, and second stack layer 1220-2 includes metal of low acoustic impedance. In various embodiments, first stack layer 1220-1 can be the same as or different from first stack layer 1218-1, and second stack layer 1220-2 can be the same as or different from second stack layer 1218-2. In some embodiments, first stack layer 1220-1 includes the same material as first stack layer 1218-1, and second stack layer 1220-2 includes the same material as second stack layer 1218-2. In some embodiments, a second stack layer 1220-2 is in contact with second electrode 1216.

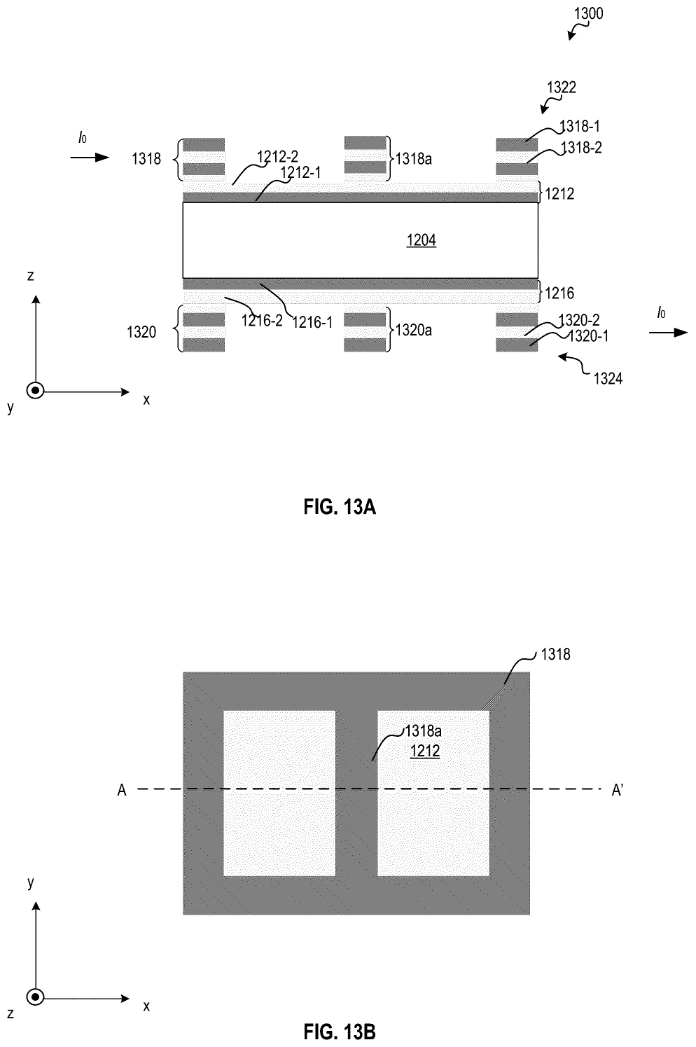

FIGS. 13A and 13B illustrate another BAW structure 1300, a transducer, with reduced electrical losses, according to some embodiments.

BAW structure 1300 may include a first electrode 1212, a second electrode 1216, and a piezoelectric layer 1204 between first electrode 212 and second electrode 1216, similar to BAW structure 1200. BAW structure 1300 may include a first conductive bridge structure 1322 electrically connected to (e.g., in contact with) first electrode 1212, and a second conductive bridge structure 1324 electrically connected to (e.g., in contact with) second electrode 1216. Similar to BAW structure 1200, first conductive bridge structure 1322 and second conductive bridge 1324 may be in contact with the respective electrode and biased to conduct electrical current. In some embodiments, different from BAW structure 1200, first conductive bridge structure 1322 and second conductive bridge structure 1324 may each be in contact with the respective electrode at the peripheral area and the central area of the respective electrode. Bias may be applied on first conductive bridge structure 1222 and second conductive bridge structure 1224. FIG. 13A shows an example direction where electric current lo flows into and out of the transducer. As show in FIGS. 13A and 13B, first conductive bridge structure 1322 and second conductive bridge structure 1324 may each form a “peripheral ring” contacting the respective electrode in the x-and y-directions (e.g., having stripe shapes), as well as a central piece extending in the y-direction. First conductive bridge structure 1322 and second conductive bridge structure 1324 may expose the rest of the respective electrode outside the central area and the peripheral ring. In some embodiments, first conductive bridge structure 1322 may include a central piece 1318a (e.g., in the y-direction) in contact with portions of first conductive bridge structure 1322 in the peripheral area, and second conductive bridge structure 1324 may include a central piece 1320a (e.g., in the y-direction) in contact with portions of second conductive bridge structure 1322 in the peripheral area. In some embodiments, central pieces 1318a and 1320a may align with each other in the z-direction. In some embodiments, first and second conductive bridge structures 1322 and 1324 are aligned in the z-direction. In some embodiments, first electrode 1212 and second electrode 1216 have the same dimensions in the x-and y-directions. In some embodiments, the structures and materials of 1318a and 1320a may be similar to those of the respective conductive bridge structure, and the detailed description is not repeated herein.

Those skilled in the art will recognize improvements and modifications to the preferred embodiments of the present disclosure. All such improvements and modifications are considered within the scope of the concepts disclosed herein and the claims that follow.

1. A bulk acoustic wave (BAW) structure, comprising a transducer that comprises:
a first electrode;
a second electrode;
a piezoelectric layer between the first electrode and the second electrode; and
a conductive bridge structure extending in a lateral direction and in contact with the first electrode at a central stripe area of the first electrode.

2. The BAW structure of claim 1, wherein the transducer further comprises:
a second conductive bridge structure extending in contact with the second electrode at a central stripe area of the second electrode, the central stripe area of the first electrode and the central stripe area of the second electrode are aligned with each other in the lateral direction.

3. The BAW structure of claim 2, wherein:
the conductive bridge structure is in contact with a first peripheral area of the first electrode; and
the second conductive bridge structure is in contact with a second peripheral area of the second electrode, the first peripheral area and the second peripheral area being on opposite sides of the central stripe areas of the first electrode and the second electrode.

4. The BAW structure of claim 1, wherein the transducer further comprises:
a second conductive bridge structure over and in contact with the second electrode at two peripheral areas of the second electrode, the two peripheral areas being on opposite sides of the central stripe area of the first electrode.

5. The BAW structure of claim 2, wherein the transducer further comprises:
a third conductive bridge structure extending in a second lateral direction, intersecting with the conductive bridge structure, and in contact with the first electrode at a second central stripe area of the first electrode; and
a fourth conductive bridge structure extending in the second lateral direction, intersecting with the second conductive bridge structure, and in contact with the second electrode at a second central stripe area of the second electrode, and
wherein the second central stripe area of the first electrode and the second central stripe area of the second electrode are aligned with each other, the second lateral direction being different from the lateral direction.

6. The BAW structure of claim 3, wherein the transducer further comprises:
a third conductive bridge structure extending in a second lateral direction, intersecting with the conductive bridge structure, and in contact with the first electrode at a second central stripe area of the first electrode; and
a fourth conductive bridge structure extending in the second lateral direction, intersecting with the second conductive bridge structure, and in contact with the second electrode at a second central stripe area of the second electrode, and
wherein the second central stripe area of the first electrode and the second central stripe area of the second electrode are aligned with each other, the second lateral direction being different from the lateral direction.

7. The BAW structure of claim 4, wherein the transducer further comprises:
a third conductive bridge structure extending in a second lateral direction, intersecting with the conductive bridge structure, and in contact with the first electrode at a second central stripe area of the first electrode, the second lateral direction being different from the lateral direction, and
wherein the second conductive bridge structure is in contact with the second electrode at all peripheral areas of the second electrode.

8. The BAW structure of claim 1, further comprising a second conductive bridge structure extending in contact with the second electrode at a second central stripe area of the second electrode, the central stripe area of the first electrode and the second central stripe area of the second electrode are aligned with each other in the lateral direction and separated by a gap, wherein:
the central stripe areas of the first electrode and the second electrode divide the transducer into a first sub-transducer and a second sub-transducer;
the first electrode is divided to a first electrode of the first sub-transducer and a first electrode of the second sub-transducer, and the second electrode is divided to a second electrode of the first sub-transducer and a second electrode of the second sub-transducer; and
the first conductive bridge structure is electrically disconnected from the second conductive bridge structure.

9. The BAW structure of claim 8, wherein:
the conductive bridge structure is in contact with a peripheral area of the first electrode in the first sub-transducer;
the second conductive bridge structure is in contact with a peripheral area of the second electrode in the second sub-transducer; and
a projection of the conductive bridge structure has no overlap with a projection of the second conductive bridge structure.

10. The BAW structure of claim 9, wherein the second conductive bridge structure is in a same plane of the conductive bridge structure, and is electrically connected to the second electrode of the second sub-transducer with a conductive via through the piezoelectric layer.

11. The BAW structure of claim 8, wherein:
the conductive bridge structure is in contact with a peripheral area of the first electrode in the first sub-transducer;
the second conductive bridge structure is in contact with a peripheral area of the first electrode in the second sub-transducer and is in a same plane of the conductive bridge structure; and
the first electrode of the first sub-transducer is electrically disconnected from the first electrode of the second sub-transducer and electrically connected to the second electrode of the second sub-transducer with a conductive via through the piezoelectric layer, a projection of the conductive via being overlapped with the central stripe area;
the second electrode of the first sub-transducer is electrically disconnected from the second electrode of the second sub-transducer and is electrically connected to the first electrode of the second sub-transducer with another conductive via through the piezoelectric layer, a projection of the other conductive via being overlapped with the second central stripe area.

12. The BAW structure of claim 1, wherein the transducer further comprises:
a second conductive structure in contact with the second electrode at all peripheral areas of the second electrode; and
a vertical projection of the first electrode is surrounded by a vertical projection of the second conductive structure.

13. The BAW structure of claim 12, wherein the second conductive structure is disposed in a single plane.

14. The BAW structure of claim 12, wherein a vertical projection of the central stripe area is a line of symmetry of the vertical projection of the second conductive bridge structure.

15. The BAW structure of claim 14, wherein:
the second electrode comprises a first portion and a second portion; and
vertical projections of the first portion and the second portion of the second electrode are disposed on opposite sides of the vertical projection of the central stripe area and have no overlap with each other.

16. The BAW structures of claim 1, wherein the conductive bridge structure comprise a stack of alternating one or more first metal layers and one or more second metal layers in contact with the first electrode, the first metal layers and the second metal layers having different acoustic impedances.

17. The BAW structure of claim 2, wherein the second conductive bridge structure comprises alternating one or more first metal layers and one or more second metal layers, the first metal layers and the second metal layers having different acoustic impedances.

18. The BAW structure of claim 1, wherein an area outside central stripe area of the first electrode is covered with a dielectric material.

19. A bulk acoustic wave (BAW) structure, comprising a transducer that comprises:
a first electrode;
a second electrode;
a piezoelectric layer between the first electrode and the second electrode;
a first conductive structure in contact with a peripheral area of the first electrode; and
a second conductive structure in contact with a peripheral area of the second electrode,
wherein the first conductive structure or the second conductive structure comprises a stack of alternating one or more first metal layers and one or more second metal layers, the first metal layers and the second metal layers having different acoustic impedances.

20. The BAW structure of claim 19, wherein:
the first conductive structure comprises a central portion in contact with the first electrode along a line of symmetry of the transducer and a peripheral portion of the first conductive structure; and
the second conductive structure comprises a central portion in contact with the second electrode along the line of symmetry of the transducer and a peripheral portion of the second conductive structure,
wherein the central portion of the first conductive structure or the central portion of the second conductive structure comprises another stack of alternating one or more first metal layers and one or more second metal layers.
